(19) United States
(12) Patent Application Publication
(10) Pub. No.: US 2026/0182336 A1
(43) Pub. Date: Jun. 25, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Yu-Feng LIN, Hsinchu (TW); Yu-Syuan CAI, Hsinchu (TW); Yu-Ting HSIAO, Taichung City (TW); Hong-Ming WU, Taichung City (TW); Min-Hsiu HUNG, Tainan City (TW); Zih-Syuan YANG, Hsinchu (TW); Wei-Jung LIN, Hsinchu City (TW); Chih-Wei CHANG, Hsin-Chu (TW); Ming-Hsing TSAI, Chu-Pei City (TW)

(21) Appl. No.: 19/171,809

(22) Filed: Apr. 7, 2025

Related U.S. Application Data
(60) Provisional application No. 63/738,215, filed on Dec. 23, 2024.

(51) Int. Cl. H01L 23/522; H01L 21/67; H01L 21/768; H01L 23/528; H01L 23/532; H01L 23/538

(52) U.S. Cl. CPC H10W 20/42; H10P 72/0462; H10W 20/056; H10W 20/069; H10W 20/074; H10W 20/081; H10W 20/096; H10W 20/43; H10W 20/48; H10W 70/611; H10W 70/685

(57) ABSTRACT

A dielectric layer of a semiconductor device may be treated using an oxidation treatment process to tune the dielectric constant of the dielectric layer. For example, an etch stop layer (ESL) in an interconnect layer of the semiconductor device may be formed of a high dielectric constant (high-k) dielectric material, which provides etch selectivity for the ESL relative to other dielectric layers in the interconnect layer. A recess may be formed through the ESL and through the dielectric layers, and a conductive structure may be formed in the recess. Prior to formation of the conductive structure, an oxidation treatment operation may be performed to oxidize the exposed ends of the ESL in the recess. The oxidation treatment may lower the dielectric constant of the ends of the ESL, which may result in the ends of the ESL being less susceptible to current leakage through tunneling, hot-carrier injection, and/or thermionic emission.

### CROSS-REFERENCE TO RELATED APPLICATION

This patent application claims priority to U.S. Provisional Patent Application No. 63/738,215, filed on Dec. 23, 2024, and entitled “SEMICONDUCTOR DEVICE AND METHODS OF FORMATION.” The disclosure of the prior application is considered part of and is incorporated by reference into this patent application.

### BACKGROUND

An interconnect layer (sometimes referred to as a back end region or a back end of line (BEOL) region) is a region of a semiconductor device that includes a plurality of layers of conductive structures that are arranged to carry signals and/or to provide power distribution throughout the semiconductor device. The plurality of layers of conductive structures may include various vertically-arranged layers of interconnect structures (e.g., vias) and layers of metallization structures (e.g., trenches, conductive lines, traces).

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1C are diagrams of a portion of an example semiconductor device described herein.

FIG. 2 is a diagram of an example implementation of an elemental composition of a portion of a semiconductor device described herein.

FIGS. 3A-3E are diagrams of an example implementation of forming a semiconductor device described herein.

FIGS. 4A-4H are diagrams of an example implementation of forming a source/drain interconnect structure described herein.

FIGS. 5A-5H are diagrams of an example implementation of forming a gate interconnect structure described herein.

FIGS. 6A-6H are diagrams of an example implementation of forming a source/drain interconnect structure and a gate interconnect structure described herein.

FIGS. 7A-7C are diagrams of example implementations of source/drain contact structures and source/drain interconnect structures for a semiconductor device described herein.

FIG. 8 is a flowchart of an example process associated with forming a semiconductor device described herein.

FIG. 9 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An interconnect layer of a semiconductor device may be formed above a device layer of the semiconductor device. The device layer may include a substrate layer of the semiconductor device and integrated circuit devices (e.g., transistors, capacitor, diodes, memory cells) in and/or on the semiconductor substrate. A layer of contact structures (referred to as source/drain contacts) may be included between the integrated circuit devices and the interconnect layer, and may electrically connect the integrated circuit devices to a bottom-most layer of conductive structures (referred to as source/drain interconnects and gate interconnects) in the interconnect layer.

To form a conductive structure of the interconnect layer on a contact structure, a recess may be formed through one or more dielectric layers to expose the top surface of the contact structure. The material of the conductive structure may then be deposited on the top surface of the contact structure so that the conductive structure and the contact structure are electrically coupled.

An interconnect layer typically includes a plurality of dielectric layers. These dielectric layers may include etch stop layers (ESLs) and interlayer dielectric (ILD) layers. The ESLs and ILD layers may be arranged in an alternating manner. The ESLs provide an etch stop function, which enables various shapes and/or configurations of recesses to be formed for the conductive structures of the interconnect layer, and may enable dual damascene and other complex processes to be performed in the interconnect layer. To provide etch selectivity between the ESLs and ILD layers, the ESLs and ILD layers may be formed of different dielectric materials. For example, the ILD layers may be formed of low dielectric constant (low-k) dielectric materials such as silicon oxide (SiOₓ), whereas the ESLs may be formed of high dielectric constant (high-K) dielectric materials such as silicon nitride (SiₓN_{y}). While the high-k dielectric materials of the ESLs provide etch selectivity relative to the material of the ILD layers and resist etching by etchants used for the ILD layers, the high-k dielectric materials of the ESLs may be more susceptible to current leakage than the low-k dielectric material of the ILD layers.

The semiconductor industry is constantly working toward shrinking processing node sizes in an effort to increase transistor density and/or to reduce power consumption in manufactured semiconductor devices. While the increased transistor density and/or the reduced power consumption may increase the efficiency and/or processing power of the semiconductor devices, reducing the sizes of structures and/or layers in the semiconductor devices may cause undesirable side effects that may compromise the performance of the semiconductor devices. For example, the reduced sizes of structures and/or layers in a semiconductor device, in combination with the susceptibility of the high-k material of ESLs to current leakage, may result in increased current leakage between the source/drain interconnects and gate interconnects of transistors in the semiconductor device, between the source/drain interconnects and the gate structures of the transistors, and/or between the gate interconnects and the source/drain contacts of the transistors.

In some implementations described herein, one or more dielectric layers in a semiconductor device are treated using an oxidation treatment process to tune the dielectric constant of the one or more dielectric layers. For example, an ESL in an interconnect layer of the semiconductor device may be formed of a high-k dielectric material such as silicon nitride (SiₓN_{y}), which provides etch selectivity for the ESL relative to other dielectric layers (e.g., ILD layers) in the interconnect layer. The etch selectivity of the ESL may facilitate formation of a recess through the ESL and through other dielectric layers in the interconnect layer for formation of a conductive structure (e.g., a source/drain interconnect, a gate interconnect) in the recess.

After formation of the recess, an oxidation treatment operation may be performed to oxidize the exposed ends of the ESL in the recess using an oxygen-based reactant. Oxygen (O) in the oxygen-based reactant and silicon (Si) in the ends of the ESL exposed in the recess may react to form regions of oxide-containing dielectric material in and/or on the ends of the ESL. The conductive structure may be formed in the recess after the oxidation treatment operation.

The band gap of the regions of oxide-containing dielectric material in and/or on the ends of the ESL is greater than that of the band gap of the material (e.g., silicon nitride) of the ESL. The greater band gap of the regions of oxide-containing dielectric material in and/or on the ends of the ESL results in the regions of oxide-containing dielectric material being less susceptible to current leakage through tunneling, hot-carrier injection, and/or thermionic emission. In this way, the oxidation treatment process may be used to achieve low current leakage in the semiconductor device between the source/drain interconnects and gate interconnects of transistors in the semiconductor device, between the source/drain interconnects and the gate structures of the transistors, and/or between the gate interconnects and the source/drain contacts of the transistors.

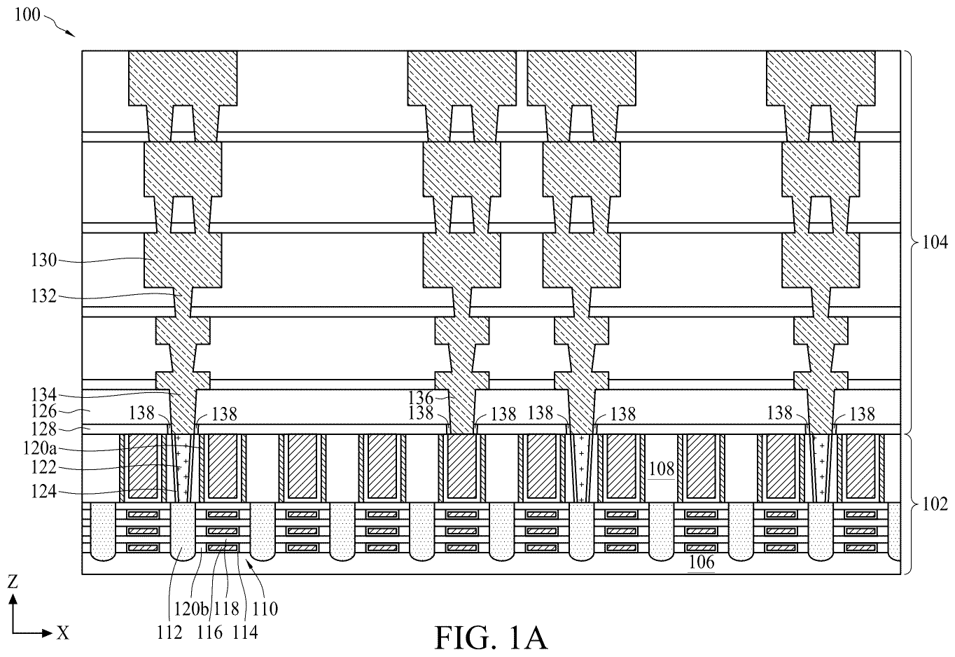

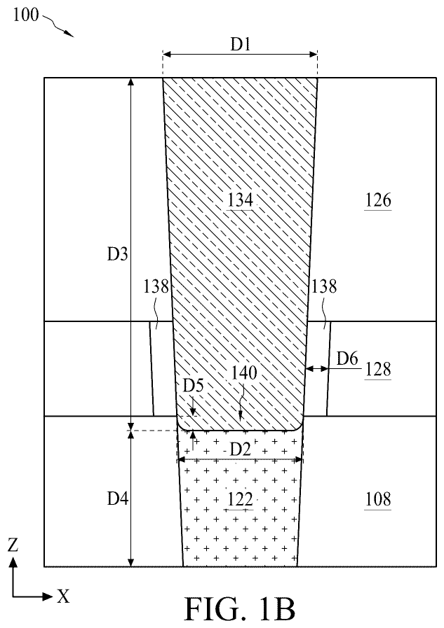

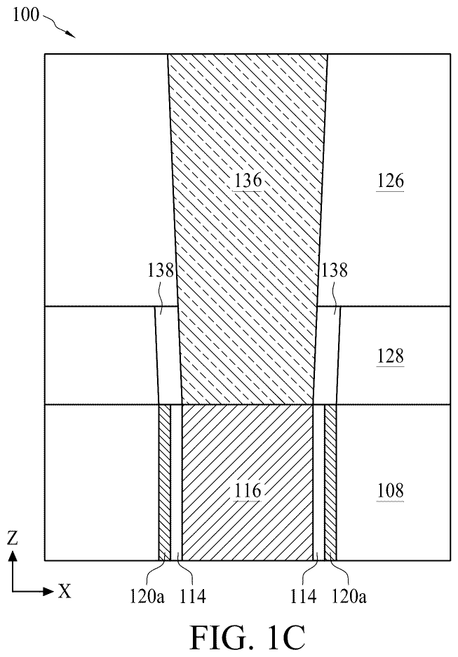

FIGS. 1A-1C are diagrams of a portion of an example semiconductor device 100 described herein. The semiconductor device 100 may include a system on chip (SoC) device, a logic device such as a central processing unit (CPU) or a graphics processing unit (GPU), a memory device (e.g., a high bandwidth memory (HBM) device), a panel driver device, an integrated circuit (IC) driver, a radio frequency (RF) power amplifier, a display driver IC (DDIC), and/or another type of semiconductor device.

As shown in FIG. 1A, the semiconductor device 100 may include a device layer 102 and an interconnect layer 104 above the device layer 102 in a z-direction in the semiconductor device 100. The device layer 102 includes a substrate layer 106. The substrate layer 106 may correspond to a portion of a semiconductor wafer on which the semiconductor device 100 is formed. The substrate layer 106 includes a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate layer 106 may extend in an x-direction and/or in a y-direction in the semiconductor device 100.

A dielectric layer 108 is included over the substrate layer 106. The dielectric layer 108 includes an interlayer dielectric (ILD) layer (e.g., an ILD0 layer), an etch stop layer (ESL), and/or another type of dielectric layer. The dielectric layer 108 includes dielectric material(s) that enable various portions of the substrate layer 106 to be selectively etched or protected from etching, and/or may electrically isolate integrated circuit devices 110 in the device layer 102. The dielectric layer 108 includes a silicon nitride (SiₓN_{y}), an oxide (e.g., a silicon oxide (SiOₓ) and/or another oxide material), and/or another type of dielectric material. The dielectric layer 108 may extend in the x-direction and/or in a y-direction in the semiconductor device 100.

The integrated circuit devices 110 may be included in and/or on the substrate layer 106, and/or in in the dielectric layer 108 in the device layer 102 of the semiconductor device 100. The integrated circuit devices 110 include transistors (e.g., planar transistors, fin field effect transistors (finFETs), gate all around (GAA) transistors), pixel sensors, capacitors, resistors, inductors, photodetectors, transceivers, transmitters, receives, optical circuits, and/or other types of semiconductor devices.

An integrated circuit device 110 may include a plurality of source/drain regions 112 that are grown and/or otherwise formed on and/or around portions of the substrate layer 106. “Source/drain region(s)” may refer to a source or a drain, individually or collectively, dependent upon the context. The source/drain regions 112 may be formed by epitaxially growing doped semiconductor regions and/or by another semiconductor process. In some implementations, the source/drain regions 112 are formed in recessed portions in the substrate layer 106. The recessed portions may be formed by strained source/drain (SSD) etching of the substrate layer 106 and/or another type etching operation. In some implementations, the source/drain regions 112 are formed in recesses that are formed in an alternating stack of channel layers and sacrificial layers (e.g., silicon germanium (SiGe) layers.

An integrated circuit device 110 may further include a gate dielectric layer 114 between a gate structure 116 and channel layers 118 of the integrated circuit device 110. The channel layers 118 may extend between the source/drain regions 112 of the integrated circuit device 110, and gate dielectric layer 114 and the gate structure 116 may wrap around two or more sides of the channel layers 118. In some implementations, the gate dielectric layer 114 and the gate structure 116 wrap around all four sides of the channel layers 118. In these implementations, the integrated circuit device 110 may be referred to as a nanostructure transistor such as a GAA transistor.

The channel layers 118 may include nanoscale layers of semiconductor material, such as silicon (Si), silicon germanium (SiGe), and/or doped silicon, among other examples. The channel layers 118 may be formed from silicon nanosheets that are formed as part of a nanosheet stack above the substrate layer 106.

In some implementations, the gate dielectric layer 114 includes a low dielectric constant (low-k) dielectric material such as silicon oxide (SiOₓ). In some implementations, the gate dielectric layer 114 includes a high dielectric constant (high-k) dielectric material such as hafnium oxide (HfOₓ).

The gate structure 116 may be located laterally between the source/drain regions 112. In some implementations, the gate structure 116 is formed of a polysilicon material. In these implementations, the polysilicon material may be doped with one or more types of dopants (e.g., p-type dopants, n-type dopants) to tune a work function of the gate structure 116.

In some implementations, the gate structure 116 is formed of one or more metal materials (e.g., tungsten (W), titanium (Ti), cobalt (Co), and/or another metal). In these implementations, the gate structure 116 may include one or more work function metal layers (e.g., p-type metal layers, n-type metal layers) for tuning the work function of the gate structure 116. The work function metal layer(s) may be included between the gate dielectric layer 114 and the gate structure 116.

A p-type work function metal layer may include one or more p-type metals, such as tungsten (W), cobalt (Co), titanium nitride (TiN), tungsten nitride (WN), and/or another metal having a work function that is greater than approximately 4.7 electron volts (eV), among other examples. A p-type work function metal layer may be included to tune the work function of the gate structure 116 such that the work function is adjusted close to the valence band of the material of the channel layers 118.

An n-type work function metal layer may include one or more metal materials that tune or adjust the work function of the gate structure 116 near the conduction band of the material of the channel layers 118 of the semiconductor device 100. In some implementations, an n-type work function metal layer may include titanium aluminum (TiAl). In some implementations, an n-type work function metal layer includes titanium aluminum carbon (TiAlC). In some implementations, an n-type work function metal layer includes another aluminum-containing metal. In some implementations, another n-type metal material is included in an n-type work function metal layer.

Various spacers may be included in the integrated circuit devices 110. For example, sidewall spacers 120a may be included on the sidewalls of the gate structure 116 to provide electrical isolation for the gate structure 116, among other examples. In some implementations, the sidewall spacers 120a are in contact with the gate dielectric layer 114.

In some implementations, the sidewall spacers 120a are in contact with the work function metal layer. The sidewall spacers 120a may include a silicon oxide (SiOₓ), a silicon nitride (SiₓN_{y}), a silicon oxycarbide (SiOC), a silicon oxycarbonitride (SiOCN), and/or another suitable material.

As another example, inner spacers 120b may be included laterally between the gate structure 116 and the source/drain regions 112 of an integrated circuit device 110. The inner spacer 120b may be included to reduce parasitic capacitance in the integrated circuit device 110 and to protect the source/drain regions 112 from being etched in a nanosheet release operation to remove sacrificial layers between the channel layers 118. The inner spacers 120b may include a silicon nitride (SiₓN_{y}), a silicon oxide (SiOₓ), a silicon oxynitride (SiON), a silicon oxycarbide (SiOC), a silicon carbon nitride (SiCN), a silicon oxycarbonnitride (SiOCN), and/or another dielectric material.

The source/drain regions 112 are electrically coupled and/or physically coupled with source/drain contact structures 122. The source/drain contact structures 122 may include contact vias, contact plugs, and/or another type of contact structures that electrically connect the source/drain regions 112 of the integrated circuit devices 110 with the interconnect layer 104 of the semiconductor device 100. The source/drain contact structures 122 include cobalt (Co), ruthenium (Ru), tungsten (W), molybdenum (Mo), copper (Cu), and/or another electrically conductive material or metal material. One or more liner layers 124 may be included on sidewalls of the source/drain contact structures 122. The liner layer(s) 124 may include a barrier layer that is included to prevent or minimize diffusion of materials from the source/drain contact structures 122 to the surrounding dielectric layers, an adhesion layer or glue layer that is included to promote adhesion between the source/drain contact structures 122 and the surrounding dielectric layers, and/or another type of liner. Examples of materials for the liner layer(s) 124 include titanium nitride (TiN), tantalum nitride (TaN), and/or another suitable liner material.

The interconnect layer 104 of the semiconductor device 100 is included above the device layer 102 and above the integrated circuit devices 110 in the z-direction in the semiconductor device 100. The interconnect layer 104 includes a plurality of dielectric layers that are arranged in a direction (e.g., the z-direction) that is approximately perpendicular to the substrate layer 106. The dielectric layers may include ILD layers 126 and ESLs 128 that are arranged in an alternating manner in the z-direction. The ILD layers 126 and the ESLs 128 may extend in the x-direction and/or in the y-direction in the semiconductor device 100.

The ILD layers 126 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 126 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

The ESLs 128 may each include a silicon nitride (SiₓN_{y}), silicon carbide (SiC), silicon oxynitride (SiON), and/or another suitable dielectric material. In some implementations, an ILD layer 126 and an ESL 128 include different dielectric materials to provide etch selectivity to enable various structures to be formed in the interconnect layer 104.

The interconnect layer 104 may further include a plurality of layers of conductive structures in the dielectric layers (e.g., the ILD layers 126 and the ESLs 128) of the interconnect layer 104. The conductive structures in the interconnect layer 104 may be interconnected to enable signals and/or power to be distributed throughout the semiconductor device 100 through the interconnect layer 104. The conductive structures include a combination of metallization structures 130 and interconnect structures 132. The metallization structures 130 may include trenches, conductive traces, and/or other types of conductive structures that primarily extend in the x-direction and/or in the y-direction in the interconnect layer 104. The interconnect structures 132 may include vias, plugs, conductive columns, and/or other types of conductive structures that primarily extend in the z-direction in the semiconductor device. In some implementations, a conductive structure in the interconnect layer 104 includes a dual damascene structure, which includes a combination of a metallization structure 130 and an interconnect structure 132.

The metallization structures 130 and the interconnect structures 132 may each include one or more electrically conductive materials such as tungsten (W), cobalt (Co), ruthenium (Ru), molybdenum (Mo), titanium (Ti), aluminum (Al), copper (Cu), gold (Au), and/or a combination thereof, among other examples of electrically conductive materials. In some implementations, one or more liner layers are included between the metallization structures 130 and/or the interconnect structures 132 and the surrounding dielectric layers in the interconnect layer 104. The one or more liner layers may include barrier liners, adhesion liners, and/or another type of liners. Examples of materials for the one or more liners include tantalum nitride (TaN) and/or titanium nitride (TiN), among other examples.

In some implementations, the metallization structures 130 and the interconnect structures 132 of the interconnect layer 104 may be arranged in a vertical manner (e.g., in the z-direction). In other words, a plurality of stacked metallization structures 130 and interconnect structures 132 may extend between the device layer 102 and a top of the interconnect layer 104 to facilitate electrical signals and/or power to be routed between the device layer 102 and connection structures (not shown) of the semiconductor device 100.

The plurality of stacked metallization structures 130 may be arranged in layers that may be referred to as M-layers, and the plurality of stacked interconnect structures 132 may be arranged in layers that may be referred to as V-layers. A bottom-most layer of interconnect structures 132 in the interconnect layer 104 may be referred to as a V0 layer, and may include source/drain interconnect structures 134 that are electrically coupled and/or physically coupled to the source/drain contact structures 122 of one or more integrated circuit devices 110, and gate interconnect structures 136 that are electrically coupled and/or physically coupled to the gate structures 116 of one or more integrated circuit devices 110. The source/drain interconnect structures 134 are referred to source/drain vias (VDs), and the gate interconnect structures 136 are referred to as gate vias (VGs). In some implementations, gate contacts (not shown) are included between the gate structures 116 and the gate interconnect structures 136.

A bottom-most layer of metallization structures 130 coupled to the bottom-most layer of interconnect structures 132 may be referred to as a metal-0 (M0) layer, and may be located above the bottom-most layer of interconnect structures 132 (e.g., the layer that includes the source/drain interconnect structures 134 and the gate interconnect structures 136) in the interconnect layer 104. Thus, the metallization structures 130 in the M0 layer may be electrically coupled and/or physically coupled with the source/drain interconnect structures 134 and/or the gate interconnect structures 136.

Additional layers of conductive structures may be arranged in a similar manner in the interconnect layer 104. For example, a layer of interconnect structures 132 may be referred to as a via-1 (V1) layer that is located above and electrically coupled and/or physically coupled to the layer of metallization structures 130 in the M0 layer. A layer of metallization structures 130 may be referred to as a metal-1 (M1) layer that is located above and electrically coupled and/or physically coupled to the layer of interconnect structures 132 in the V1 layer. A layer of interconnect structures 132 may be referred to as a via-2 (V2) layer that is located above and electrically coupled and/or physically coupled to the layer of metallization structures 130 in the M1 layer. A layer of metallization structures 130 may be referred to as a metal-2 (M2) layer that is located above and electrically coupled and/or physically coupled to the layer of interconnect structures 132 in the V2 layer. A layer of interconnect structures 132 may be referred to as a via-3 (V3) layer that is located above and electrically coupled and/or physically coupled to the layer of metallization structures 130 in the M2 layer. A layer of metallization structures 130 may be referred to as a metal-3 (M3) layer that is located above and electrically coupled and/or physically coupled to the layer of interconnect structures 132 in the V3 layer. A layer of interconnect structures 132 may be referred to as a via-4 (V4) layer that is located above and electrically coupled and/or physically coupled to the layer of metallization structures 130 in the M3 layer. A layer of metallization structures 130 may be referred to as a metal-4 (M4) layer that is located above and electrically coupled and/or physically coupled to the layer of interconnect structures 132 in the V4 layer. In some implementations, the interconnect layer 104 includes a different quantity of layers of metallization structures 130 and/or a different quantity of layers of interconnect structures 132 than the quantities shown in FIG. 1A.

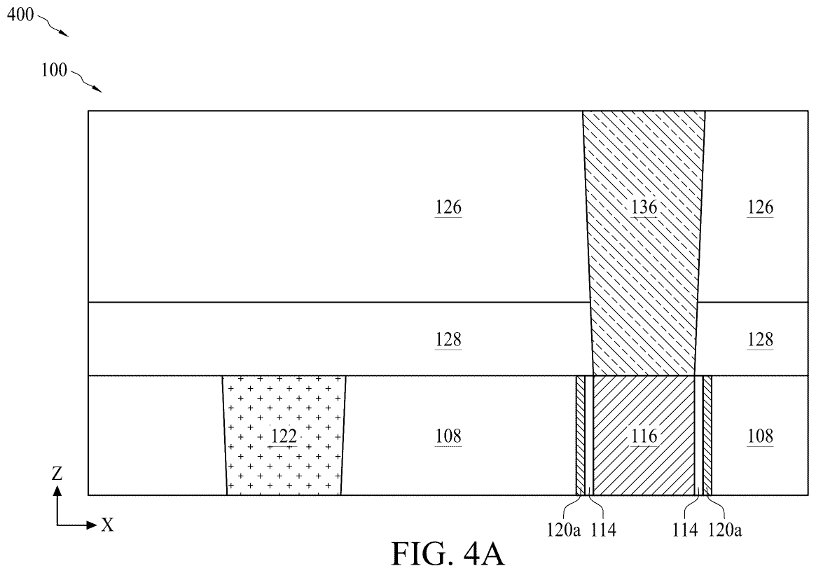

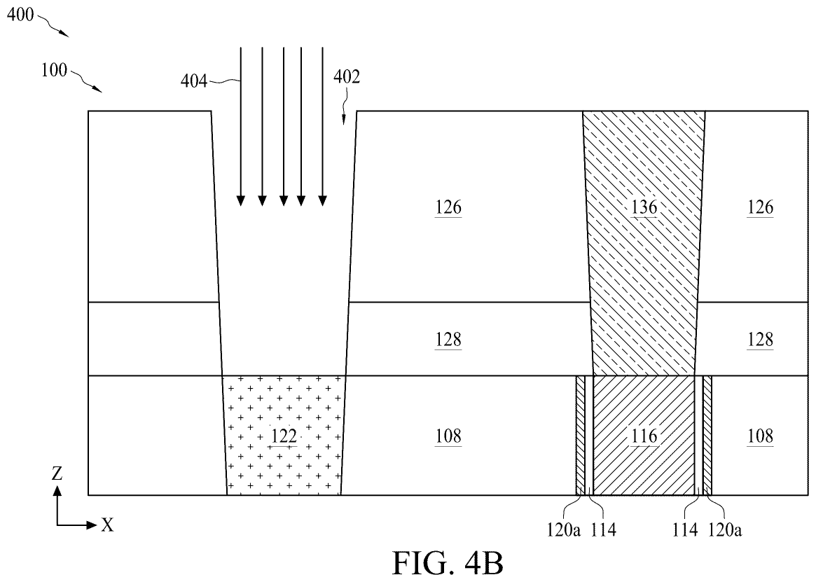

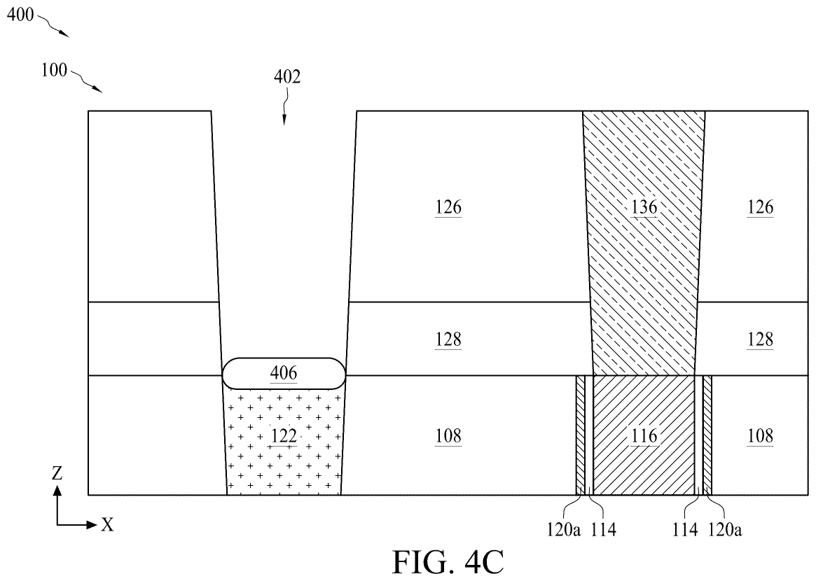

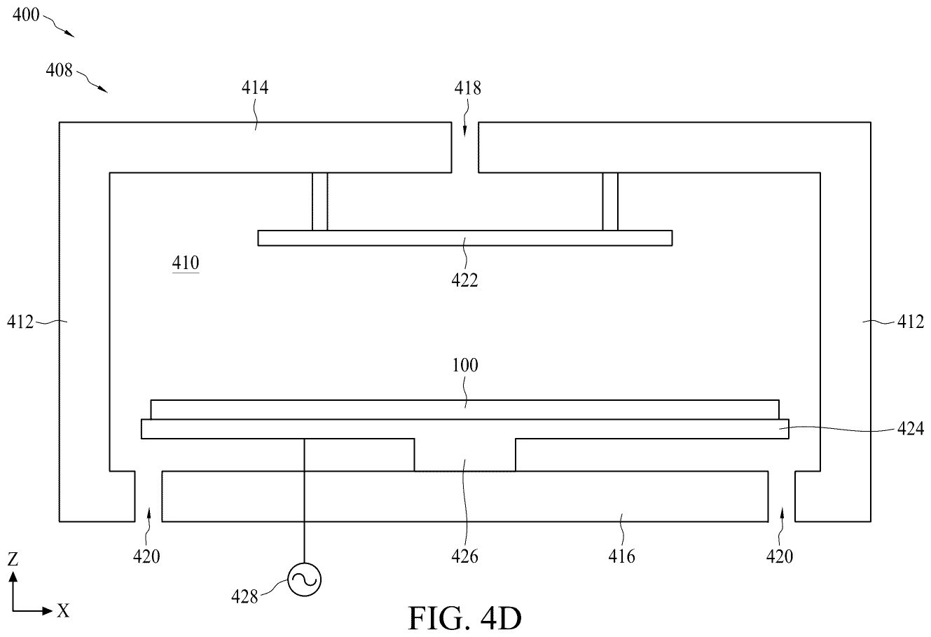

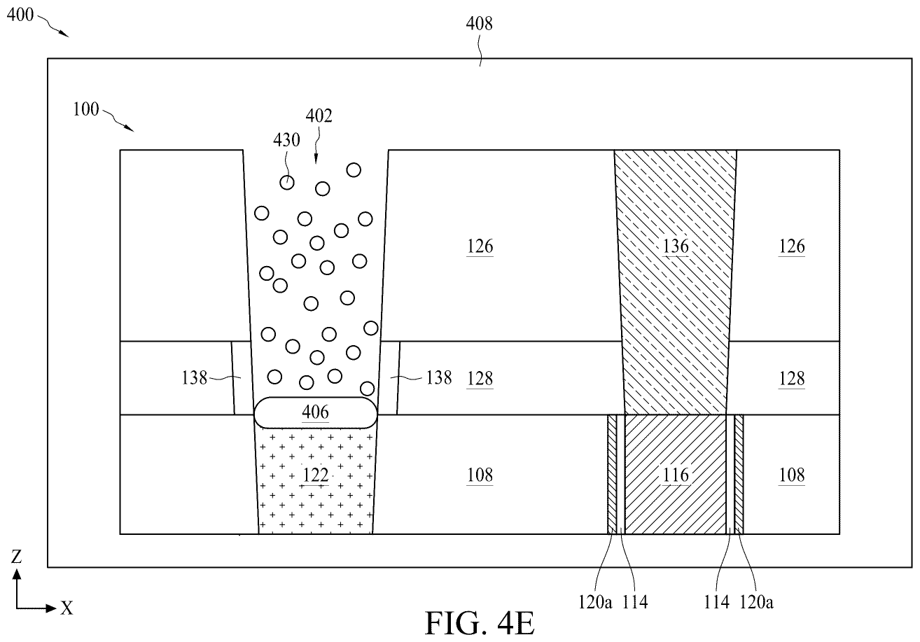

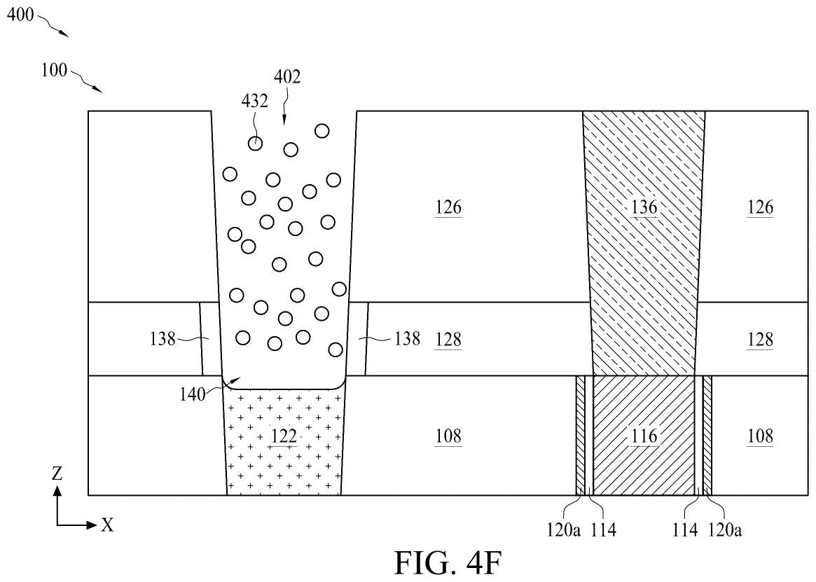

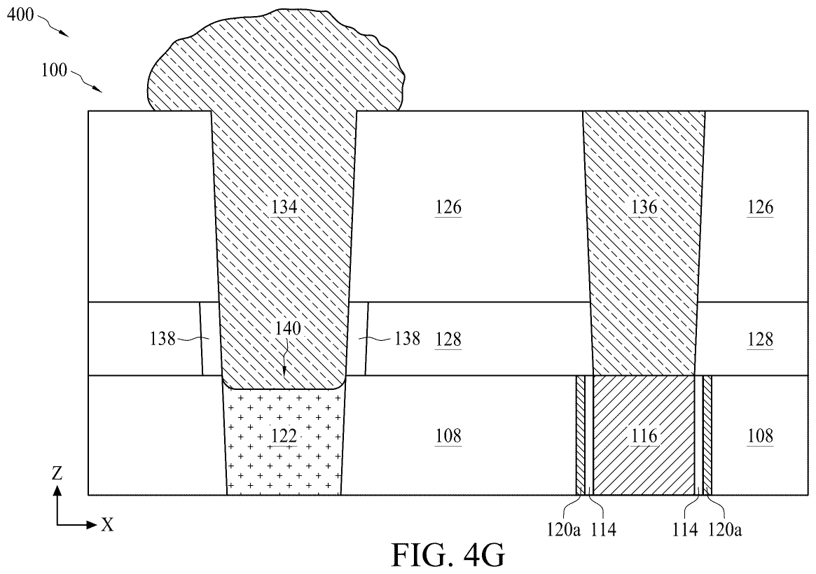

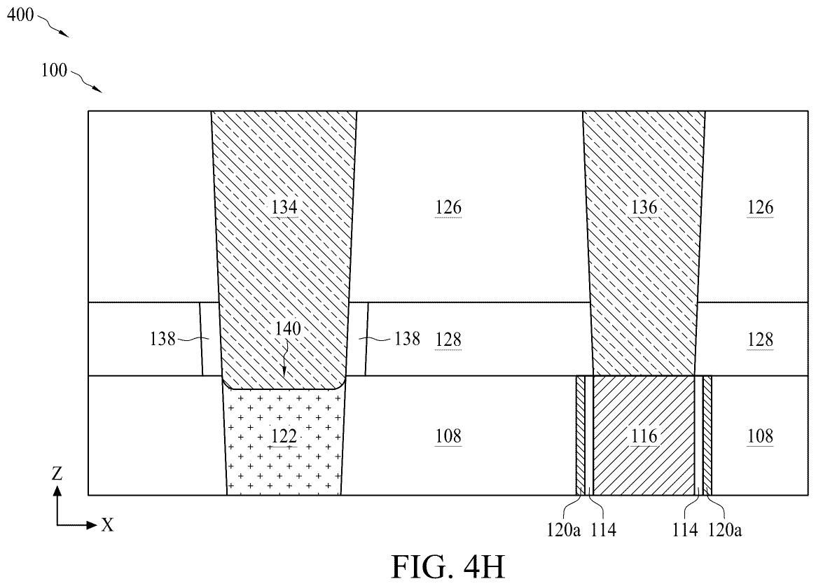

As further shown in FIG. 1A, oxide regions 138 may be located on ends of an ESL 128 through which the source/drain interconnect structures 134 and/or through which the gate interconnect structures 136 extend. The oxide regions 138 may be formed by processes described herein, such as in connection with FIGS. 4A-4H, 5A-5H, 6A-6H, 8, and/or 9, among other examples.

The oxide regions 138 contain a different material composition than the ESL 128. For example, the ESL 128 may contain a high-k dielectric material such as silicon nitride (SiₓN_{y} such as Si₃N₄), whereas the oxide regions 138 may contain a low-k dielectric material such as silicon oxide (SiOₓ) or silicon oxide that contains a small amount of nitrogen (N). The presence of nitrogen in the oxide regions 138 may result from the oxide regions 138 being formed from the ESL 128, such as by oxidizing the ends of the ESL 128 during processes for forming the source/drain interconnect structures 134 and/or for forming the gate interconnect structures 136.

The lower dielectric constant of the material of the oxide regions 138 provides for lower parasitic capacitance between adjacent interconnect structures, such as adjacent source/drain interconnect structures 134, adjacent gate interconnect structures 136, and or a source/drain interconnect structure 134 and an adjacent gate interconnect structures 136. In some implementations, the material of the oxide regions 138 may have a dielectric constant that is approximately 3.9 or less, whereas the material of the ESL 128 may have a dielectric constant that is approximately 8 to approximately 10. In some implementations, the material of the oxide regions 138 may have a dielectric constant that is less than approximately 8, whereas the material of the ESL 128 may have a dielectric constant that is greater than approximately 8. However, other values and ranges are within the scope of the present disclosure.

The material of the oxide regions 138 may also have a higher band gap than the material of the ESL 128. For example, the material of the oxide regions 138 may have a band gap that is greater than approximately 8 electron volts, whereas the material of the ESL 128 may have a band gap that is included in a range of approximately 4.55 electron volts to approximately 5.8 electron volts. However, other values and ranges are within the scope of the present disclosure.

The higher band gap of the material of the oxide regions 138 provides for lower current leakage between adjacent interconnect structures, such as adjacent source/drain interconnect structures 134, adjacent gate interconnect structures 136, and or a source/drain interconnect structure 134 and an adjacent gate interconnect structures 136. The higher band gap of the material of the oxide regions 138 results in a greater amount of energy needed for charge carriers to move through the oxide regions 138 between interconnect structures, thereby inhibiting current leakage.

FIG. 1B illustrates a detailed view of a connection between a source/drain contact structure 122 and a source/drain interconnect structure 134 of the semiconductor device 100. As shown in FIG. 1B, the source/drain contact structure 122 may be included in the dielectric layer 108. An ESL 128 of the interconnect layer 104 may be included above the source/drain contact structure 122. An ILD layer 126 (e.g., an ILD1 layer) of the interconnect layer 104 may be included above the ESL 128.

As further shown in FIG. 1B, the source/drain interconnect structure 134 is located above and/or on the source/drain contact structure 122 such that the source/drain contact structure 122 and the source/drain interconnect structure 134 are vertically arranged (e.g., in the z-direction) in the semiconductor device 100. The top surface of the source/drain contact structure 122 is located below the ESL 128 and includes a recess 140 that is filled in by the bottom of the source/drain interconnect structure 134. Thus, the top surface of the source/drain contact structure 122 is recessed below the ESL 128, and the bottom of the source/drain interconnect structure 134 is recessed in the top surface of the source/drain contact structure 122.

The recess 140 may provide increased surface area contact between the top surface of the source/drain contact structure 122 and the bottom of the source/drain interconnect structure 134. The source/drain contact structure 122 and the source/drain interconnect structure 134 may include different types of metals (e.g., the source/drain contact structure 122 may include tungsten (W) and the source/drain interconnect structure 134 may include copper (Cu)), and the hetero-metal interface between the source/drain contact structure 122 and the source/drain interconnect structure 134 may result in increased contact resistance between the source/drain contact structure 122 and the source/drain interconnect structure 134. Thus, the recess 140 may negate some of the increased contact resistance, and/or may enable a lower overall contact resistance to be achieved. However, in other implementations, the top surface of the source/drain contact structure 122 is substantially flat and planar.

As further shown in FIG. 1B, the oxide regions 138 may be located laterally between segments of the sidewalls of the source/drain interconnect structure 134 and the ESL 128, whereas other segments of the sidewalls of the source/drain interconnect structure 134 may be in contact with the ILD layer 126. Bottom surfaces of the oxide regions 138 may be in contact with a top surface of the dielectric layer 108, and top surfaces of the oxide regions 138 may be in contact with the bottom surface of the ILD layer 126.

In implementations in which the top surface of the source/drain contact structure 122 contains the recess 140, the bottom surface of the source/drain interconnect structure 134 may be lower in the semiconductor device 100 than the bottom surfaces of the oxide regions 138. In implementations in which the top surface of the source/drain contact structure 122 is substantially planar, the bottom surface of the source/drain interconnect structure 134 and the bottom surfaces of the oxide regions 138 may be approximately co-planar.

In some implementations, the top surfaces of the oxide regions 138 and the top surface of the ESL 128 may be approximately co-planar. In some implementations, the bottom surfaces of the oxide regions 138 and the bottom surface of the ESL 128 may be approximately co-planar.

As further shown in FIG. 1B, in some implementations, the sidewalls of the source/drain interconnect structure 134 may be tapered (e.g., angled outward so that the lateral width of the source/drain interconnect structure 134 increases between the bottom and the top of the source/drain interconnect structure 134). In these implementations, the sidewalls of the oxide regions 138 facing the source/drain interconnect structure 134 may be angled in a similar manner. This may occur because the recess in which the source/drain interconnect structure 134 was formed had angled or tapered sidewalls, and the oxide regions 138 were formed through the recess prior to formation of the source/drain interconnect structure 134. In some implementations, the sidewalls of the oxide regions 138 facing the source/drain interconnect structure 134 may have another profile, such as a rounded profile or a substantially vertical profile.

As further shown in FIG. 1B, the source/drain contact structure 122, the source/drain interconnect structure 134, and/or the oxide regions 138 may have one or more example dimensions. An example dimension D1 corresponds to a top lateral width of the source/drain interconnect structure 134 (e.g., a top width), and another example dimension D2 corresponds to a bottom lateral width of the source/drain interconnect structure 134 (e.g., a bottom width). The dimension D1 and the dimension D2 may each be included in a range of approximately 3 nanometers to approximately 50 nanometers. However, other values and ranges are within the scope of the present disclosure. In some implementations, the dimension D1 is greater than the dimension D2 such that the sidewalls of the source/drain interconnect structure 134 are angled outward from a center of the source/drain interconnect structure 134, and such that the lateral width of the source/drain interconnect structure 134 decreases from the dimension D1 to the dimension D2.

In some implementations, the dimension D2 also corresponds to a top lateral width of the top surface of the source/drain contact structure 122. In some implementations, the top lateral width of the top surface of the source/drain contact structure 122 is greater than the dimension D2 such that the top surface of the source/drain contact structure 122 extends laterally outward from the bottom of the source/drain interconnect structure 134.

Another example dimension D3 corresponds to a z-direction height (or vertical thickness) of the source/drain interconnect structure 134. In some implementations, the dimension D3 is included in a range of approximately 15 nanometers to approximately 45 nanometers. However, other values and ranges are within the scope of the present disclosure.

Another example dimension D4 corresponds to a z-direction height (or vertical thickness) of the source/drain contact structure 122. In some implementations, the dimension D4 is included in a range of approximately 15 nanometers to approximately 45 nanometers. However, other values and ranges are within the scope of the present disclosure.

In some implementations, a ratio of the dimension D3 to the dimension D4 is included in a range of approximately 1:4 to approximately 45:1. However, other values and ranges are within the scope of the present disclosure.

Another example dimension D5 includes a z-direction depth of the recess 140. The z-direction depth of the recess 140 corresponds to the vertical (e.g., z-direction) distance between the lowest part of the recess 140 and the bottom of the ESL 128. In some implementations, the dimension D5 is included in a range of approximately 0.5 nanometers to approximately 20 nanometers. If dimension D5 is outside of this range, the metal-oxide layer that forms on the top surface of the source/drain contact structure 122 may not be fully removed, resulting in increased contact resistance between the source/drain contact structure 122 and the source/drain interconnect structure 134. However, other values and ranges are within the scope of the present disclosure.

Another example dimension D6 includes a lateral thickness (e.g., in the x-direction, in the y-direction) of an oxide region 138. In some implementations, the dimension D6 is included in a range of approximately 0.1 nanometers to approximately 10 nanometers. If the lateral thickness of the oxide region 138 is less than approximately 0.1 nanometers, the oxide region 138 may not provide sufficient current leakage blocking. If the lateral thickness of the oxide region 138 is greater than approximately 10 nanometers, the oxidation process for forming the oxide region 138 may result in excessive formation of metal-oxides on the top surface of the source/drain contact structure 122, thereby increasing the difficulty, cost, and/or time of a cleaning the metal-oxides from the source/drain contact structure 122. However, other values and ranges are within the scope of the present disclosure.

FIG. 1C illustrates a detailed view of a connection between a gate structure 116 and a gate interconnect structure 136 of the semiconductor device 100. As shown in FIG. 1C, the gate structure 116 may be included in the dielectric layer 108. An ESL 128 of the interconnect layer 104 may be included above the gate structure 116. An ILD layer 126 (e.g., an ILD1 layer) of the interconnect layer 104 may be included above the ESL 128.

As further shown in FIG. 1C, the gate interconnect structure 136 is located above and/or on the gate structure 116 such that the gate structure 116 and the gate interconnect structure 136 are vertically arranged (e.g., in the z-direction) in the semiconductor device 100. The top surface of the gate structure 116 may be located below the ESL 128.

As further shown in FIG. 1C, the oxide regions 138 may be located laterally between segments of the sidewalls of the gate interconnect structure 136 and the ESL 128, whereas other segments of the sidewalls of the gate interconnect structure 136 may be in contact with the ILD layer 126. Bottom surfaces of the oxide regions 138 may be in contact with the sidewall spacers 120a and/or the gate dielectric layer 114 on the sidewalls of the gate structure 116, and top surfaces of the oxide regions 138 may be in contact with the bottom surface of the ILD layer 126. In some implementations, the bottom surfaces of the oxide regions 138 may also be in contact with the dielectric layer 108.

In some implementations, the bottom surface of the gate interconnect structure 136 and the bottom surfaces of the oxide regions 138 may be approximately co-planar. In some implementations, the top surfaces of the oxide regions 138 and the top surface of the ESL 128 may be approximately co-planar. In some implementations, the bottom surfaces of the oxide regions 138 and the bottom surface of the ESL 128 may be approximately co-planar.

As further shown in FIG. 1C, in some implementations, the sidewalls of the gate interconnect structure 136 may be tapered (e.g., angled outward so that the lateral width of the gate interconnect structure 136 increases between the bottom and the top of the gate interconnect structure 136). In these implementations, the sidewalls of the oxide regions 138 facing the gate interconnect structure 136 may be angled in a similar manner. This may occur because the recess in which the gate interconnect structure 136 was formed had angled or tapered sidewalls, and the oxide regions 138 were formed through the recess prior to formation of the gate interconnect structure 136. In some implementations, the sidewalls of the oxide regions 138 facing the gate interconnect structure 136 may have another profile, such as a rounded profile or a substantially vertical profile.

As indicated above, FIGS. 1A-1C are provided as an example. Other examples may differ from what is described with regard to FIGS. 1A-1C.

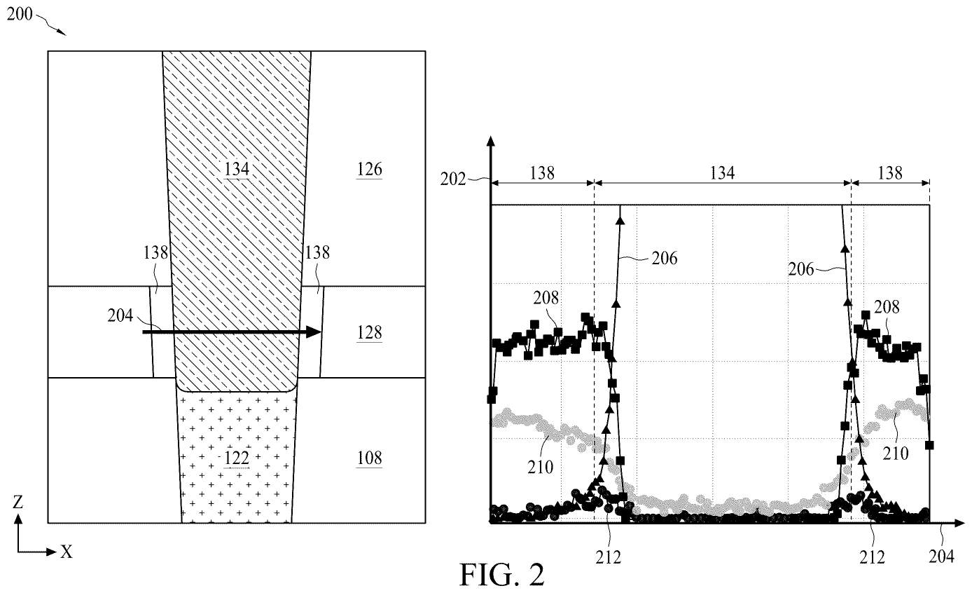

FIG. 2 is a diagram of an example implementation 200 of an elemental composition of a portion of the semiconductor device 100 described herein. The portion of the semiconductor device 100 corresponds to portions of oxide regions 138 and an adjacent source/drain interconnect structure 134 (or a gate interconnect structure 136), and the elemental composition is illustrated along a direction 204 that is a lateral direction (e.g., an x-direction, a y-direction) across the portions of the oxide regions 138 and the adjacent source/drain interconnect structure 134. The elemental composition is illustrated as a function of elemental intensity 202 along the direction 204.

As shown in FIG. 2, the source/drain interconnect structure 134 (or a gate interconnect structure 136) may primarily contain a metal element 206 such as tungsten (W), copper (Cu), and/or ruthenium (Ru), among other examples. On opposing sides of the source/drain interconnect structure 134, the oxide regions 138 may contain a composition of silicon (Si) 208, oxygen (O) 210, and nitrogen (N) 212 in implementations in which the ESL 128 is formed of silicon nitride (Si₃N₄). The silicon 208 and the nitrogen 212 contained in the oxide regions 138 may come from the oxide regions 138 being formed from the ESL 128. In particular, the ends of the ESL 128 may be treated with an oxidizer such as oxygen (O₂), ozone (O₃), and/or water vapor (H₂O), among other examples, to form the oxide regions 138, which provides the oxygen 210 contained in the oxide regions 138.

As further shown in FIG. 2, the concentration of oxygen 210 (indicated in the elemental composition by the elemental intensity 202 of the oxygen 210) is greater than the concentration of nitrogen 212 (indicated in the elemental composition by the elemental intensity 202 of the nitrogen 212) in the oxide regions 138. The greater concentration of oxygen 210 reduces the dielectric constant of the oxide regions 138 relative to the ESL 128 and increases the band gap of the oxide regions 138 relative to the ESL 128, thereby enabling reduced parasitic capacitance and reduced current leakage to be achieved for the source/drain interconnect structure 134.

As indicated above, FIG. 2 is provided as an example. Other examples may differ from what is described with regard to FIG. 2.

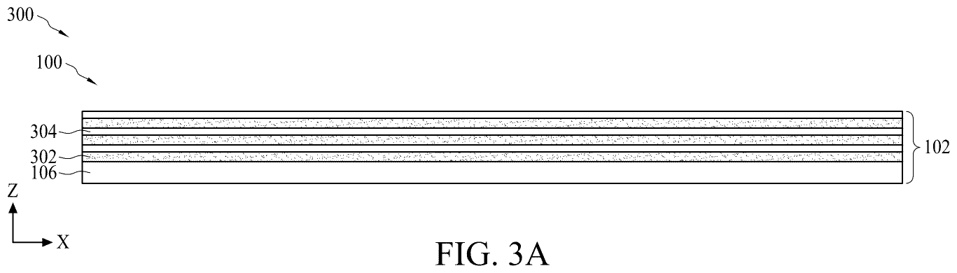

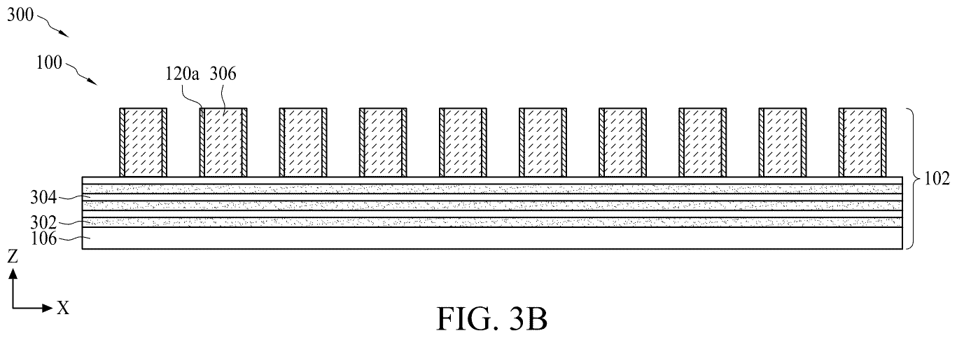

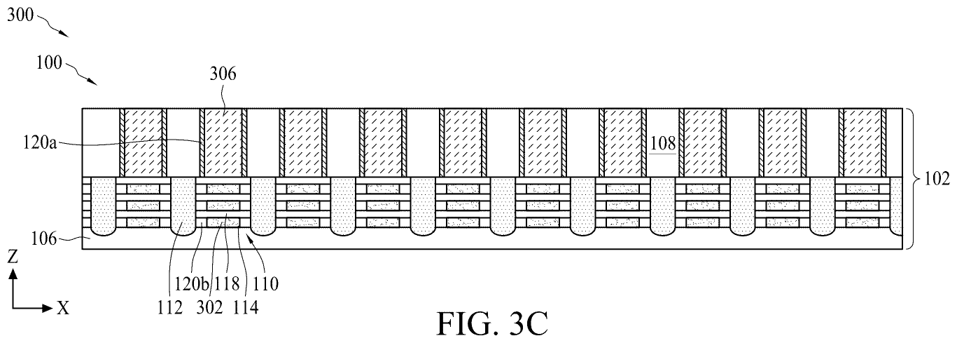

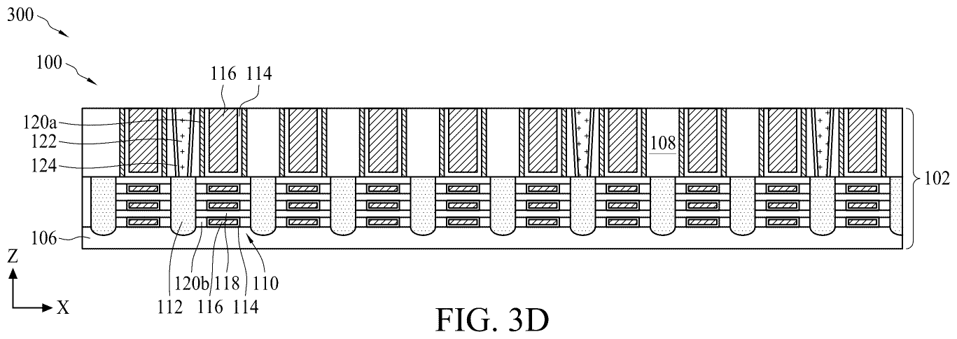

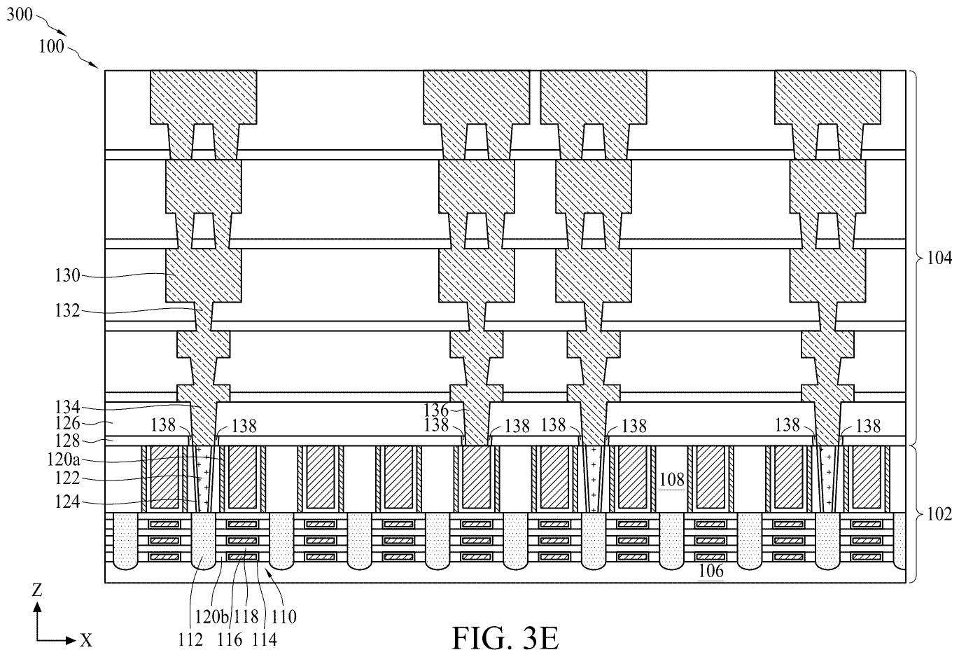

FIGS. 3A-3E are diagrams of an example implementation 300 of forming the semiconductor device 100 described herein. In some implementations, one or more of the semiconductor processing operations described in connection with FIGS. 3A-3E may be performed using one or more semiconductor processing tools, such as a deposition tool, an exposure tool, a developer tool, an etch tool, a planarization tool, an ion implantation tool, a wafer/die transport tool, and/or another type of semiconductor processing tool.

As shown in FIG. 3A, the substrate layer 106 is provided. The substrate layer 106 may be provided in the form of a semiconductor wafer such as a silicon (Si) wafer, a silicon-on-insulator (SOI) wafer, and/or another type of semiconductor work piece. The semiconductor device 100 may be formed on the semiconductor wafer with other semiconductor devices.

A layer stack may be formed on the substrate layer 106. The layer stack may be referred to as a superlattice. The layer stack may include a plurality of alternating layers that are arranged in a direction (e.g., the z-direction) that is approximately perpendicular to the substrate layer 106. For example, the layer stack may include vertically alternating layers of sacrificial layers 302 and nanostructure channel layers 304 above the substrate layer 106.

The quantity of the sacrificial layers 302 and the quantity of the nanostructure channel layers 304 illustrated in FIG. 3A are examples, and other quantities of the sacrificial layers 302 and the nanostructure channel layers 304 are within the scope of the present disclosure.

The sacrificial layers 302 enable a vertical distance to be defined between adjacent nanostructure channels that are formed from the nanostructure channel layers 304, and serve as placeholder layers for subsequently-formed gate structures of the integrated circuit devices 110 of the semiconductor device 100 that are formed around the nanostructure channels.

The sacrificial layers 302 include a first material composition, and the nanostructure channel layers 304 include a second material composition. In some implementations, the first material composition and the second material composition are the same material composition. In some implementations, the first material composition and the second material composition are different material compositions. As an example, the sacrificial layers 302 may include silicon germanium (SiGe) and the nanostructure channel layers 304 may include silicon (Si). This enables the sacrificial layers 302 and/or the nanostructure channel layers 304 to be selectively etched (e.g., enables the sacrificial layers 302 and not the nanostructure channel layers 304 to be etched, enables the nanostructure channel layers 304 and not the sacrificial layers 302 to be etched) depending on the type of etchant that is used.

One or more types of deposition tools may be used to deposit and/or grow the alternating layers of the layer stack to include nanostructures (e.g., nanosheets) on the substrate layer 106. For example, a deposition tool may be used to grow the sacrificial layers 302 and/or the nanostructure channel layers 304 by epitaxial growth, which may include epitaxy techniques such as a molecular beam epitaxy (MBE), metalorganic chemical vapor deposition (MOCVD) process, and/or another suitable epitaxy technique. Additionally and/or alternatively, the sacrificial layers 302 and/or the nanostructure channel layers 304 may be deposited by chemical vapor deposition (CVD), physical vapor deposition (PVD), atomic layer deposition (ALD), and/or another suitable deposition technique.

In the y-direction, which is not visible in the view in FIG. 3A, the layer stack and the substrate layer 106 may be etched to form fin structures that extend in the x-direction. A fin structure may include a portion of the layer stack and a portion of the substrate layer 106 under the layer stack. The fin structures may be formed by patterning the one or more masking layers and etching based on a pattern formed in one or more of the masking layers. The one or more masking layers may be patterned using photolithography techniques, including double-patterning or multi-patterning techniques. An etch tool may be used to etch the layer stack and the substrate layer 106 based on the pattern using a dry etch technique (e.g., reactive ion etching), a wet etch technique, and/or a combination thereof. In some implementations, shallow trench isolation (STI) regions (not shown) may be formed between adjacent fin structures in the y-direction.

As shown in FIG. 3B, dummy gate structures 306 (also referred to as dummy gate stacks or temporary gate structures) may be formed over portions of the layer stack of sacrificial layers 302 and nanostructure channel layers 304. The dummy gate structures 306 may extend in the y-direction and may be arranged in the x-direction such that the dummy gate structures 306 are approximately perpendicular to the fin structures. The dummy gate structures 306 are sacrificial structures that are to be replaced by replacement gate structures or replacement gate stacks at a subsequent processing stage for the integrated circuit devices 110 of the semiconductor device 100. The dummy gate structures 306 may also be used to define source/drain (S/D) recesses in which source/drain regions of the nanostructure transistors are formed in the layer stack of sacrificial layers 302 and nanostructure channel layers 304.

The dummy gate structures 306 may include polycrystalline silicon (polysilicon or PO) or another material. The layers of the dummy gate structures 306 may be formed using various semiconductor processing techniques such depositing the layers of the dummy gate structures 306, patterning the layers of the dummy gate structures 306 to define the dummy gate structures 306, and/or other semiconductor processing techniques. The sidewall spacers 120a may be formed on the sidewalls of the dummy gate structures 306.

As shown in FIG. 3C, the source/drain regions 112 of the integrated circuit devices 110 are formed in the layer stack of sacrificial layers 302 and nanostructure channel layers 304. To form the source/drain regions 112, source/drain recesses may be formed through the layer stack of sacrificial layers 302 and nanostructure channel layers 304 in an etch operation. The source/drain recesses may be formed on opposing sides of a dummy gate structure 306 in the x-direction. The etch operation may be performed using the etch tool and may be referred to a strained source/drain (SSD) etch operation. In some implementations, the etch operation includes the use of a plasma etch technique, a wet chemical etch technique, and/or another type of etch technique.

Formation of the source/drain recesses may define the channel layers 118. The channel layers 118 may include silicon-based nanostructures (e.g., nanosheets or nanowires, among other examples) that function as the semiconductive channels of the integrated circuit devices 110 of the semiconductor device 100. The channel layers 118 are arranged in a direction (e.g., the z-direction) that is approximately perpendicular to the substrate layer 106. In other words, the channel layers 118 are vertically arranged or stacked above the substrate layer 106.

Prior to formation of the source/drain regions 112 in the source/drain recesses, the ends of the sacrificial layers 302 that are exposed in the source/drain recesses may be laterally etched in an etch operation, thereby forming cavities in the ends of the sacrificial layers 302. The inner spacers 120b may be formed in the cavities. To form the inner spacers 120b, a deposition tool may be used to deposit a layer of dielectric material in the cavities and along the sidewalls and bottom surface of the source/drain recesses. A CVD technique, a PVD technique, and ALD technique, and/or another deposition technique may be used to deposit the layer of dielectric material. An etch tool is used to subsequently remove excess material of the layer of dielectric material from the source/drain recesses such that remaining portions correspond to the inner spacers 120b in the cavities.

After formation of the inner spacers 120b, the source/drain recesses may be filled with one or more layers of epitaxial material to form the source/drain regions 112 in the source/drain recesses. For example, a deposition tool may be used to deposit a buffer region at the bottom of the source/drain recess, and a deposition tool may deposit a source/drain region 112 on the buffer region in the source/drain recess. In some implementations, a deposition tool is used to deposit a capping layer on the source/drain region 112 in the source/drain recess. As another example, a deposition tool may epitaxially grow a first layer of a source/drain region 112 (referred to as an L1) over an associated buffer region (which may be referred to as an L0), and may epitaxially grow a second layer of the source/drain region 112 (referred to as an L2, an L2-1, and/or an L2-2) over the first layer. The first layer may include a lightly doped silicon (e.g., doped with boron (B), phosphorous (P), and/or another dopant), and may be included as shielding layer to reduce short channel effects in the semiconductor device 100 and to reduce dopant extrusion or migration into the channel layers 118. The second layer may include a highly doped silicon or highly doped silicon germanium. The second layer may be included to provide a compressive stress in the source/drain regions 112 to reduce boron loss.

As further shown in FIG. 3C, the dielectric layer 108 may be formed over the source/drain regions 112 and around the dummy gate structures 306. The dielectric layer 108 may fill in areas between the dummy gate structures 306. In some implementations, a contact etch stop layer (CESL) is conformally deposited (e.g., by a deposition tool) over the source/drain regions 112 prior to formation of the dielectric layer 108. The dielectric layer 108 is then formed on the CESL. The CESL may provide a mechanism to stop an etch process when forming source/drain contacts 122 for the source/drain regions 112. The CESL may be formed of a dielectric material having a different etch selectivity from adjacent layers or components. The CESL may include or may be a nitrogen containing material, a silicon containing material, and/or a carbon containing material. Furthermore, the CESL may include or may be silicon nitride (SiₓN_{y}), silicon carbon nitride (SiCN), carbon nitride (CN), silicon oxynitride (SiON), silicon carbon oxide (SiCO), or a combination thereof, among other examples. The CESL may be deposited using a deposition process, such as ALD, CVD, or another deposition technique.

As shown in FIG. 3D, a replacement gate process may be performed to replace the dummy gate structures 306 with the gate structures 116 of the integrated circuit devices 110. A dummy gate removal operation may be performed to remove the dummy gate structures 306 from the semiconductor device 100. The removal of the dummy gate structures 306 leaves behind openings (or recesses) in the dielectric layer 108, and provides access to the underlying sacrificial layers 302. The dummy gate structures 306 may be removed in one or more etch operations. Such etch operations may include a plasma etch technique, a wet chemical etch technique, and/or another type of etch technique.

The replacement gate process may include a nanostructure release operation (e.g., a SiGe release operation). The nanostructure release operation is performed to remove the sacrificial layers 302 (e.g., the silicon germanium layers). This results in openings between the channel layers 118 (e.g., the areas around the channel layers 118). The sacrificial layers 302 may be removed through the spaces that were previously occupied by the dummy gate structures 306. The nanostructure release operation may include the use of an etch tool to perform an etch operation to remove the sacrificial layers 302 based on a difference in etch selectivity between the material of the sacrificial layers 302 and the material of the channel layers 118, and between the material of the sacrificial layers 302 and the material of the inner spacers 120b. The inner spacers 120b may function as etch stop layers in the etch operation to protect the source/drain regions 112 from being etched.

The replacement gate operation includes forming gate dielectric layers 114 and gate structures (e.g., replacement gate structures) 116 of the integrated circuit devices 110 in the openings between the source/drain regions 112 and between the inner spacers 120b. In particular, the gate dielectric layers 114 and the gate structures 116 fill the areas between and around the channel layers 118 that were previously occupied by the sacrificial layers 302 such that the gate structures 116 fully wrap around the channel layers 118 and surround the channel layers 118. This increases control of the channel layers 118, increases drive current for the integrated circuit devices 110, and/or reduces short channel effects (SCEs) for the integrated circuit devices 110, among other examples. The gate structures 116 may also fill in the spaces that were previously occupied by the dummy gate structures 306. Portions of a gate structure 116 are formed in between pairs of channel layers 118 in an alternating vertical arrangement. In other words, the semiconductor device 100 includes one or more vertical stacks of alternating channel layers 118 and portions of a gate structure 116.

As further shown in FIG. 3D, the source/drain contact structures 122 of the integrated circuit devices 110 may be formed through the dielectric layer 108. The source/drain contact structures 122 may be formed in recesses in the dielectric layer 108. In some implementations, a pattern in a photoresist layer is used to etch the dielectric layer 108 to form the recesses. In these implementations, a deposition tool may be used to form the photoresist layer on the dielectric layer 108. An exposure tool may be used to expose the photoresist layer to a radiation source to pattern the photoresist layer. A developer tool may be used to develop and remove portions of the photoresist layer to expose the pattern. An etch tool may be used to etch the dielectric layer based on the pattern to form the recesses. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 108 based on a pattern to form the recesses.

The source/drain contact structures 122 may be formed in the recesses such that the source/drain contact structures 122 land on the source/drain regions 112. A deposition tool may be used to deposit the material of the source/drain contact structures 122 in the recesses using a CVD technique, a PVD technique, an ALD technique, an electroplating technique, and/or another suitable deposition technique. The material of the source/drain contact structures 122 may be deposited in one or more deposition operations. In some implementations, a seed layer is first deposited, and the material of the source/drain contact structures 122 is deposited on the seed layer. In some implementations, one or more liner layers 124 are deposited in the recesses, and the source/drain contact structures 122 are deposited on the liner layer(s) 124. In some implementations, a planarization tool is used to perform a planarization operation (e.g., a chemical-mechanical planarization (CMP) operation) to planarize the source/drain contact structures 122 after the source/drain contact structures 122 are deposited such that the tops of the source/drain contact structures 122 are approximately co-planar with the top of the dielectric layer 108.

As shown in FIG. 3E, the interconnect layer 104 of the semiconductor device 100 is formed above the dielectric layer 108. One or more deposition tools are used to deposit alternating layers of ILD layers 126 and ESLs 128 in the interconnect layer 104 of the semiconductor device 100. In this way, the ILD layers 126 and ESLs 128 may be arranged in the z-direction in the semiconductor device 100. One or more deposition tools may be used to deposit each of the ILD layers 126 and each of the ESLs 128 using a PVD technique, an ALD technique, a CVD technique, an oxidation technique, and/or another suitable deposition technique. In some implementations, a planarization tool may be used to planarize the ILD layers 126 and/or the ESLs 128 after the ILD layers 126 and/or the ESLs 128 are deposited.

As further shown in FIG. 3E, a deposition tool, an exposure tool, a developer tool, an etch tool, a planarization tool, a plating tool, and/or another semiconductor processing tool may be used to perform various operations to form the source/drain interconnect structures 134 and/or the gate interconnect structures 136 at the bottom of the interconnect layer 104. One or more source/drain interconnect structures 134 may be formed on one or more source/drain contact structures 122 of one or more integrated circuit devices 110. One or more gate interconnect structures 136 may be formed on one or more gate structures 116 of one or more integrated circuit devices 110.

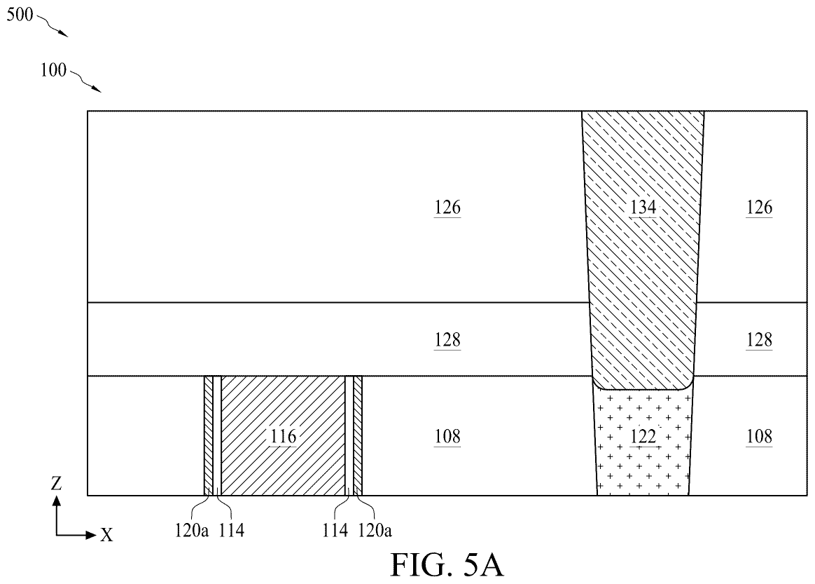

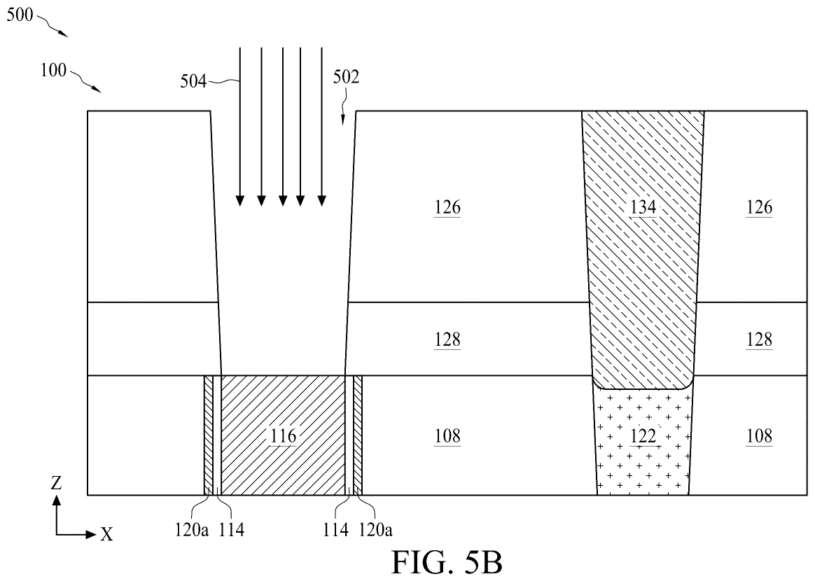

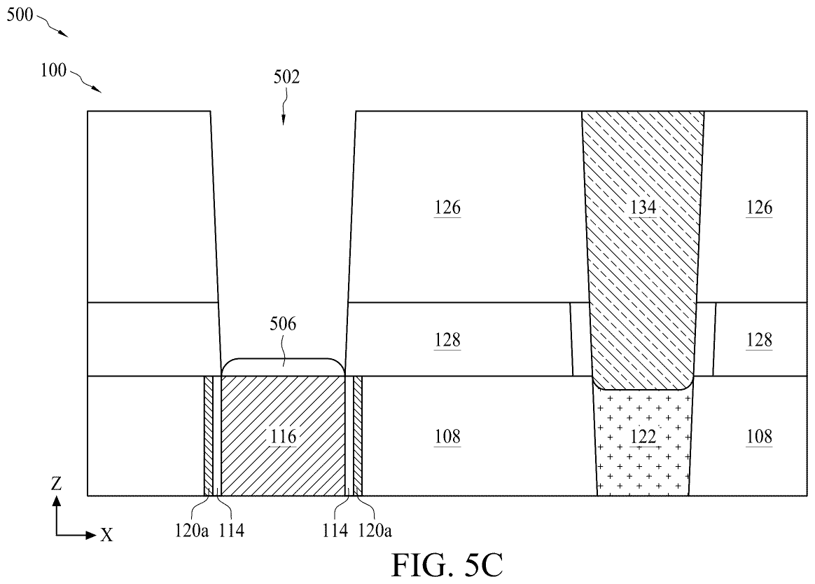

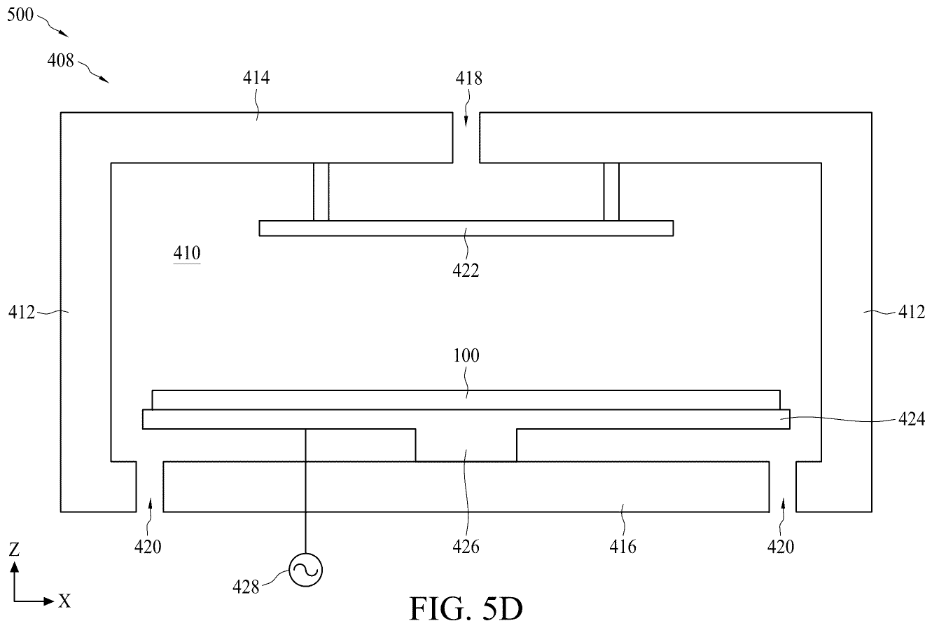

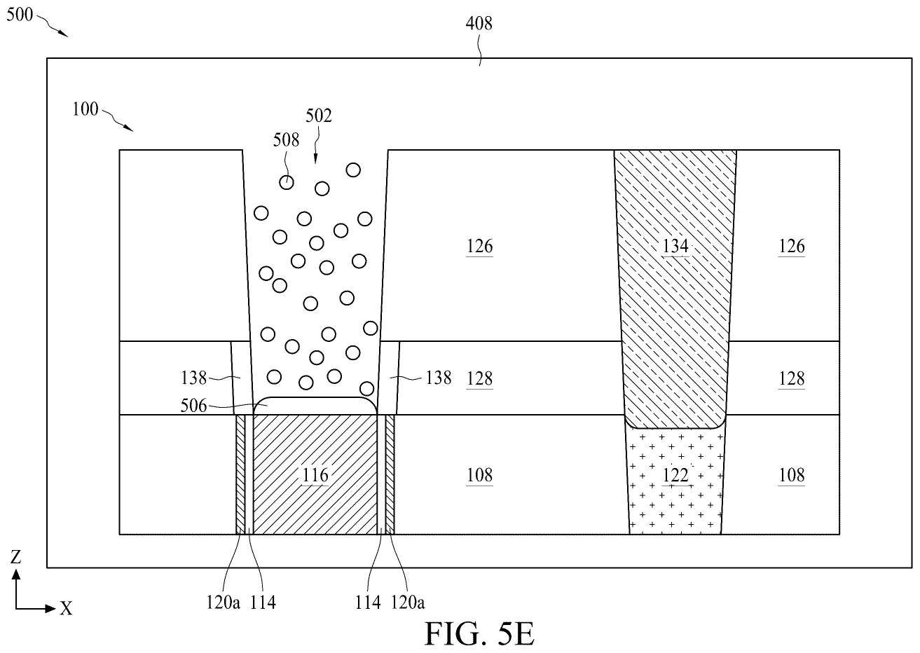

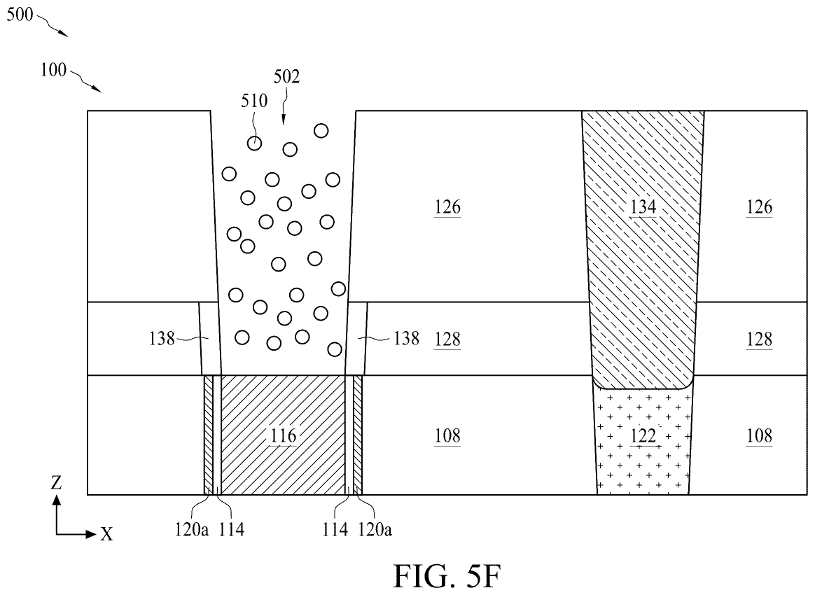

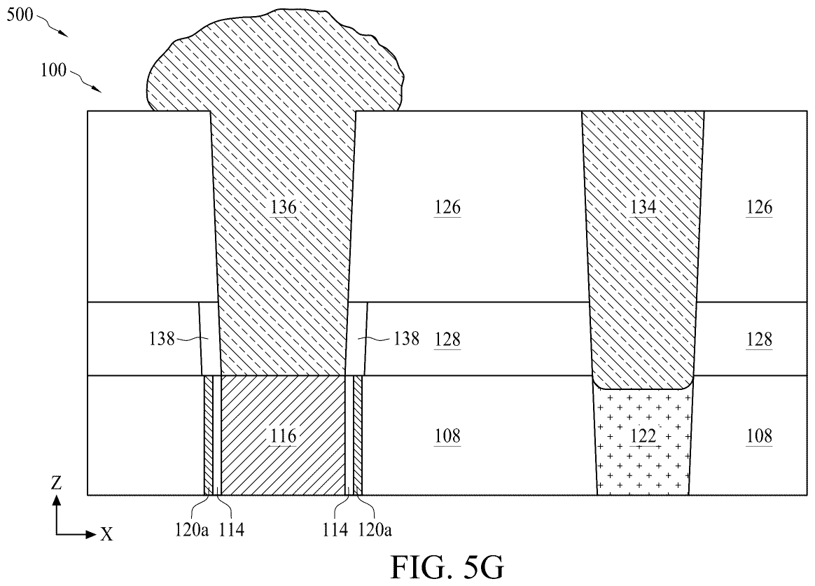

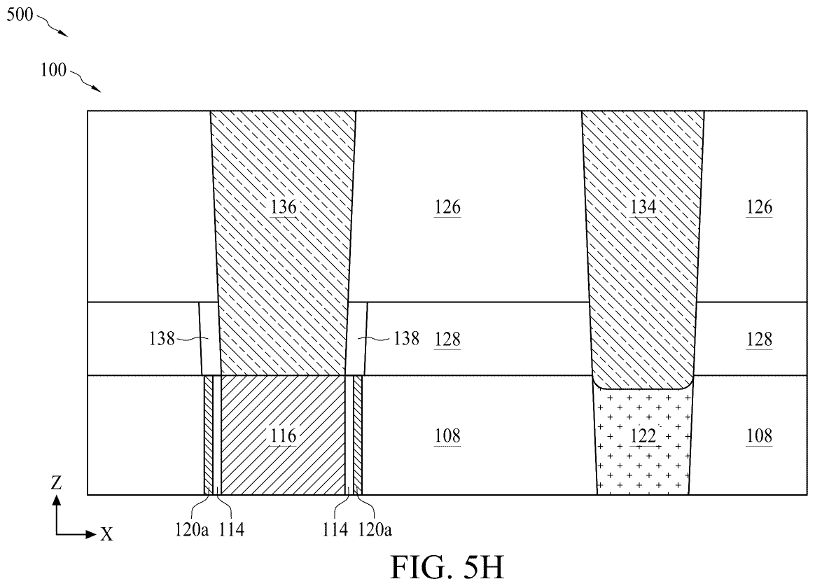

To form the layer of source/drain interconnect structures 134 and gate interconnect structures 136, an ILD layer 126 and an ESL 128 may be formed (e.g., using one or more deposition tools and/or one or more planarization tools) over the dielectric layer 108. Recesses may be formed in and/or through the ILD layer 126 and the ESL 128 (e.g., using an exposure tool, a developer tool, and/or an etch tool), and electrically conductive material may be deposited in the recesses in the ILD layer 126 and the ESL 128 (e.g., using one or more deposition tools and/or one or more planarization tools) to form the layer of source/drain interconnect structures 134 and gate interconnect structures 136. As described in greater detail in connection with FIGS. 4A-4H, 5A-5H, and/or 6A-6H, an oxidation treatment operation may be performed on the ends of the ESL 128 exposed in the recesses to oxidize the ends of the ESL 128 exposed in the recesses. Oxidation of the ends of the ESL 128 exposed in the recesses lowers the dielectric constant of the ends of the ESL 128 exposed in the recesses, resulting in formation of the oxide regions 138 on the ends of the ESL 128 exposed in the recesses.

A deposition tool, an exposure tool, a developer tool, an etch tool, a planarization tool, a plating tool, and/or another semiconductor processing tool may be used to perform various operations to form the metallization structures 130 and to form the interconnect structures 132 in the interconnect layer 104 of the semiconductor device 100. In some implementations, the metallization structures 130 and the interconnect structures 132 are formed in a plurality of vertically-arranged layers in the interconnect layer 104. For example, an ILD layer 126 and an ESL 128 may be formed (e.g., using one or more deposition tools and/or one or more planarization tools), recesses may be formed in and/or through the ILD layer 126 and the ESL 128 (e.g., using an exposure tool, a developer tool, and/or an etch tool), and a layer of metallization structures 130 (e.g., the M0 layer) may be formed in the ILD layer 126 and the ESL 128 (e.g., using one or more deposition tools and/or one or more planarization tools) above the layer of source/drain interconnect structures 134 and gate interconnect structures 136. Another ILD layer 126 and another ESL 128 may be formed, and a layer of interconnect structures 132 120a (e.g., the V1 layer) may be formed in the ILD layer 126 and the ESL 128. Additional layers of metallization structures 130 and additional layers of interconnect structures 132 may be formed in a similar manner.

One or more deposition tools may be used to deposit the metallization structures 130 and/or the interconnect structures 132 using a PVD technique, an ALD technique, a CVD technique, an electroplating technique (e.g., an electro-chemical plating technique), and/or another suitable deposition technique. In some implementations, a planarization tool may be used to planarize the metallization structures 130 and/or the interconnect structures 132 after the metallization structures 130, and/or the interconnect structures 132 are deposited.

As indicated above, FIGS. 3A-3E are provided as an example. Other examples may differ from what is described with regard to FIGS. 3A-3E.

FIGS. 4A-4H are diagrams of an example implementation 400 of forming a source/drain interconnect structure 134 described herein. In some implementations, one or more of the semiconductor processing operations described in connection with FIGS. 4A-4H may be performed using one or more semiconductor processing tools, such as a deposition tool, an exposure tool, a developer tool, an etch tool, a planarization tool, an ion implantation tool, a plasma tool, a wafer/die transport tool, and/or another type of semiconductor processing tool. In some implementations, one or more of the semiconductor processing operations described in connection with FIGS. 4A-4H may be performed as part of the process for forming the semiconductor device 100 illustrated and described in connection with FIGS. 3A-3E.

As shown in FIG. 4A, a source/drain contact structure 122 of the semiconductor device 100 may be formed in the dielectric layer 108. The ESL 128 may be formed over and/or on the dielectric layer 108, and over and/or on the source/drain contact structure 122 such that the ESL 128 covers the top surface of the source/drain contact structure 122.

As further shown in FIG. 4A, the operations described in connection with forming the source/drain interconnect structure 134 may be performed after forming a gate interconnect structure 136 of the semiconductor device 100. Alternatively, the operations described in connection with forming the source/drain interconnect structure 134 may be performed prior to forming a gate interconnect structure 136 of the semiconductor device 100.

As shown in FIG. 4B, a recess 402 is formed through the ILD layer 126 and through the ESL 128. The recess 402 is formed over the source/drain contact structure 122 so that the top surface of the source/drain contact structure 122 is exposed in the recess 402.

In some implementations, a pattern in a photoresist layer is used to etch the ILD layer 126 and/or the ESL 128 to form the recess 402. In these implementations, a deposition tool may be used to form the photoresist layer on the ILD layer 126 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern.

An etch tool may be used to etch the ILD layer 126 and/or the ESL 128 based on the pattern using an etchant 404 to form the recess 402. The etch operation includes the use of an etchant 404 to etch the ILD layer 126 and the ESL 128 to form the recess 402. In some implementations, the etch operation is a dry etch operation, and the etchant 404 is a plasma-based etchant 404 and/or a gas-based etchant 404. In some implementations, the etch operation is a wet etch operation, and the etchant 404 is a wet chemical etchant 404.

In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess 402 based on a pattern.

As shown in FIG. 4C, a metal-oxide layer 406 may form on the top surface of the source/drain contact structure 122 in the recess 402. The metal-oxide layer 406 may be referred to as a “native oxide” in that the metal-oxide layer 406 naturally forms due to oxidation of the top surface of the source/drain contact structure 122. The top surface of the source/drain contact structure 122 may oxidize due to exposure to various oxygen sources, such as oxygen in the atmosphere in the processing chamber of the etch tool, oxygen in the atmosphere in a semiconductor manufacturing facility in which the semiconductor device 100 is manufactured, and/or from another oxygen source. In some implementations, the top surface of the source/drain contact structure 122 may oxidize due to exposure to oxygen while being queued for the next processing step for the semiconductor device 100.

The metal-oxide layer 406 may correspond to a portion of the top surface of the source/drain contact structure 122 to which atmospheric oxygen has bonded. Thus, the metal-oxide layer 406 contains a metal of the source/drain contact structure 122 and extends below the ESL 128. For example, if the source/drain contact structure 122 includes tungsten (W), the metal-oxide layer 406 may include oxidized tungsten (or a tungsten oxide (WOₓ such as WO₃)). As another example, if the source/drain contact structure 122 includes molybdenum (Mo), the metal-oxide layer 406 may include oxidized molybdenum (or a molybdenum oxide (MoOₓ such as MoO₃)).

As shown in FIGS. 4D and 4E, an oxidation treatment operation may be performed on the ends of the ESL 128 exposed in the recess 402. The oxidation treatment operation may be performed in order to form the oxide regions 138 in and/or on the exposed ends of the ESL 128. The oxide regions 138 correspond to oxidized portions of the ESL 128 having an oxygen concentration that is greater than the oxygen concentration in other portions of the ESL 128.

As shown in FIG. 4D, the oxidation treatment operation may be performed using a semiconductor processing tool 408. The semiconductor processing tool 408 may include a plasma-based tool, which is a type of semiconductor processing tool that uses a plasma for one or more purposes, such as surface treatment, cleaning, etching, and/or deposition, among other examples.

As shown in FIG. 4D, the semiconductor processing tool 408 includes a processing chamber 410. The processing chamber 410 may include sidewalls 412, a lid 414 (e.g., an upper cover), and a chamber floor 416 that define an inner volume in which semiconductor substrates are processed. In some implementations, the processing chamber 410 further includes a door or another type of access point through which semiconductor substrates are provided into, and removed from, the processing chamber 410. In some implementations, the lid 414 is removable from the sidewalls 412 to provide access into the processing chamber 410 for maintenance, troubleshooting, and/or cleaning.

At the top of the processing chamber 410, an inlet 418 may be located in the lid 414. The inlet 418 may be an opening through the lid 410 through which processing gasses and/or a plasma flows into the processing chamber 410. In some implementations, the semiconductor processing tool 408 is remotely coupled, and plasma is generated by a remote plasma source and provided into the processing chamber 410 through the inlet 418. In some implementations, plasma is generated within the processing chamber 410, and gases and other reactants for generating the plasma are provided into the processing chamber through the inlet 418. The semiconductor processing tool 408 may be configured to generate a plasma using a capacitively coupled plasma (CCP) source, an inductively coupled plasma (ICP) source, a microwave source, and/or another type of a plasma source.

At the bottom of the processing chamber 410, one or more vent ports 420 may be located in the chamber floor 416. The vent port(s) 420 include openings through the chamber floor 416 through which gas-based etchant and etchant byproducts may flow out of the processing chamber 410. In some implementations, the vent port(s) 420 are coupled to vacuum pumps (not shown) that generate a negative pressure in the processing chamber 410 to facilitate the flow of process gasses, removed material, and/or byproducts, downward from the inlet 418 toward the vent port(s) 420.

In some implementations, the semiconductor processing tool 408 includes a diffusion plate 422 positioned within the processing chamber 410. The diffusion plate 422 may be located vertically between the lid 414 and the chamber floor 416 so that plasma and/or process gasses flow from the top of the processing chamber 410 through the diffusion plate 422, which promotes distribution of the plasma and/or process gasses. In some implementations, the diffusion plate 422 may be configured to control the plasma and/or process gasses to achieve a high uniformity in the distribution of the plasma and/or process gasses in the processing chamber 410. However, in other implementations, the diffusion plate 422 may be omitted from the semiconductor processing tool 408.

The vent port(s) 420 may be located below a chuck 424 that is located in the processing chamber 410. The chuck 424 may include a platform that is sized and/or shaped to accommodate a semiconductor substrate, on which the semiconductor device 100 is manufactured, on the chuck 424. For example, the semiconductor substrate may be a round semiconductor wafer, and the chuck 424 may be a round platform that conforms to the shape of the semiconductor wafer. The chuck 424 may be an electrostatic chuck that is configured to secure the semiconductor substrate by an electrostatic clamping force, a vacuum chuck that is configured to secure the semiconductor substrate by a vacuum clamping force, and/or another type of chuck that is configured to secure the semiconductor substrate by another type of clamping force.

The chuck 424 may be supported in the processing chamber 410 by a pedestal 426. In some implementations, the pedestal 426 may be configured to rotate the chuck 424 so as to rotate the semiconductor substrate on the chuck 424 during an etch operation. The chuck 424 may be coupled to a radio frequency (RF) source 428, which may be used to apply an electrical bias to the chuck 424 for controlling the flow of plasma and/or process gasses in the processing chamber 410.

To perform the oxidation treatment operation, the semiconductor device 100 (e.g., on the semiconductor substrate) may be received on the chuck 424 in the processing chamber 410 of the semiconductor processing tool 408, as shown in FIG. 4D. The semiconductor processing tool 408 may be operated to strike a plasma in the processing chamber 410 and/or external to the processing chamber 410 and provided into the processing chamber through the inlet 418. The plasma may be an oxygen-based plasma that is generated from a process gas such as an oxygen (O₂) gas, water vapor (H₂O), a nitrous oxide (NOₓ, where ₓ ranges from 1 to 3 for example) gas, and/or ozone (O₃) gas, among other examples. In some implementations, other process gasses (e.g., carrier gasses, plasma reactant gasses), such as hydrogen (H₂), nitrogen (N₂), and/or argon (Ar) are provided into the processing chamber 410 for the oxidation treatment operation.

As shown in FIG. 4E, the plasma and process gasses in the processing chamber 410 are used as a reactant 430 that is provided into the recess 402 to treat the ends of the ESL 128 that are exposed in the recess 402. The RF source 428 may be used to apply an RF bias to the chuck 424 to promote the flow of the reactant 430 into the recess 402. In some implementations, the frequency of the RF bias is included in a range of approximately 2 megahertz to approximately 10 gigahertz to promote the flow of the reactant 430 into the recess 402. However, other values and/or ranges are within the scope of the present disclosure. The power level of the RF bias may be included in a range of approximately 0.1 watt to approximately 10 kilowatts. However, other values and/or ranges are within the scope of the present disclosure. Additionally and/or alternatively, a pump may be used to pump the processing chamber 410 to at least a partial vacuum such that the pressure in the processing chamber 410 is included in a range of approximately 0.1 millitorr to approximately 30 torr to promote the flow of the reactant 430 into the recess 402. However, other values and/or ranges are within the scope of the present disclosure.

During the oxidation treatment operation, the reactant 430 reacts with the material of the ends of the ESL 128 so that oxygen atoms from the reactant 430 diffuse into the ends of the ESL 128 exposed in the recess 402. Thus, the ends of the ESL 128 after the oxidation treatment operation may contain a combination of silicon (Si), nitrogen (N), and oxygen (O). The diffused oxygen in the ends of the ESL 128 increases the oxygen concentration in the ends of the ESL 128. As a result, the ends of the ESL 128 may have an oxygen concentration that is greater than a nitrogen (N) concentration of the ends of the ESL 128.

The increased oxygen concentration in the oxide regions 138 in and/or on the ends of the ESL 128 reduces the dielectric constant of ends of the ESL 128 and increases the band gap of the ends of the ESL 128. For example, the ESL 128 may be formed of silicon nitride (SiₓN_{y}) having a dielectric constant of approximately 8 to approximately 10 and a band gap of approximately 4.55 electron volts to approximately 5.80 electron volts. The oxidation treatment operation may lower the dielectric constant of the ends of the ESL 128 (corresponding to the oxide regions 138) to approximately 3.9, and may increase the band gap of the ends of the ESL 128 (corresponding to the oxide regions 138) to approximately 9 electron volts.

The oxygen from the reactant 430 also deposits onto the ends of the ESL 128, resulting in lateral growth of the ends of the ESL 128. In other words, a portion of an end of the ESL 128 is consumed to form a portion of an oxide region 138, and a second portion of the oxide region grows on the first portion. Thus, the oxide regions 138 may be formed in and on the ends of the ESL 128. As a result of the partial growth of the ends of the ESL 128, portions of the oxide regions 138 may laterally extend over the top surface of the source/drain contact structure 122 that is exposed in the recess 402, and other portions of the oxide regions 138 may laterally extend over the top surface of the underlying dielectric layer 108.

In some implementations, the sidewalls 412, the lid 414, and/or the chamber floor 416 of the processing chamber 410 may be formed of one or more materials that resist damage to the sidewalls 412, the lid 414, and/or the chamber floor 416 during the oxidation treatment operation. For example, the material of the sidewalls 412 may include a metal-oxide material and/or a ceramic material that resists damage to the sidewalls 412 during the oxidation treatment operation. As another example, the material of the lid 414 may include a metal-oxide material and/or a ceramic material that resists damage to the lid 414 during the oxidation treatment operation. As another example, the material of the chamber floor 416 may include a metal-oxide material and/or a ceramic material that resists damage to the chamber floor 416 during the oxidation treatment operation. Such materials may include, for example, a zirconium oxide material (ZrOₓ), an aluminum oxide material (AlₓO_{y}), an yttrium (Y)-containing ceramic, an aluminum (Al)-containing ceramic, and/or a chromium (Cr)-containing ceramic.

In some implementations, the sidewalls 412, the lid 414, and/or the chamber floor 416 of the processing chamber 410 may be covered with a coating material that resists damage to the sidewalls 412, the lid 414, and/or the chamber floor 416 during the oxidation treatment operation. For example, the sidewalls 412 may be coated with a coating material that resists damage to the sidewalls 412 during the oxidation treatment operation. As another example, the lid 414 may be coated with a coating material that resists damage to the lid 414 during the oxidation treatment operation. As another example, the chamber floor 416 may be coated with a coating material that resists damage to the chamber floor 416 during the oxidation treatment operation. Such coating materials may include, for example, an alkaline earth fluoride material (e.g., calcium fluoride (CaF₂), magnesium fluoride (MgF₂), strontium fluoride (SrF₂)), a boron nitride (BN) material, a carbide material (e.g., silicon carbide (SiC), tungsten carbide (WC)), and/or a metal pnictide material (e.g., LaOFeAs, Ca₄Sb₂O), among other examples.

As shown in FIG. 4F, a pre-cleaning operation may be performed to remove the metal-oxide layer 406 from the top surface of the source/drain contact structure 122. The metal-oxide layer 406 may be removed from the top surface of the source/drain contact structure 122 to provide a bare-metal substrate on which a source/drain interconnect structure 134 is to be formed on the source/drain contact structure 122 in the recess 402.

The pre-cleaning operation includes the use of a pre-cleaning agent 432. The pre-cleaning agent 432 may include a wet chemical pre-cleaning agent, a dry gas pre-cleaning agent, and/or another type of pre-cleaning agent. The pre-cleaning agent 432 may be provided into the recess 402 (e.g., using the deposition tool or a dedicated pre-cleaning tool) so that the metal-oxide layer 406 is soaked in the pre-cleaning agent 432 for a time duration.

In some implementations, the pre-cleaning operation may be performed prior to the oxidation treatment operation described in connection with FIGS. 4D and 4E. In some implementations, the pre-cleaning operation may be performed after the oxidation treatment operation described in connection with FIGS. 4D and 4E so that additional metal-oxide material formed during the oxidation treatment operation can be removed during the pre-cleaning operation.

In some implementations, the pre-cleaning operation is performed as part of the oxidation treatment operation described in connection with FIGS. 4D and 4E. In these implementations, the pre-cleaning agent 432 corresponds to the reactant 430. Thus, the reactant 430 may be used to oxidize the ends of the ESL 128 as well as remove the metal-oxide layer 406 during the same operation.

In some implementations, the pre-cleaning agent 432 may include a metal precursor that etches or removes material from the metal-oxide layer 406. For example, the pre-cleaning agent 432 may include a halogen-based metal precursor, such as a transition metal halide. Examples of transition metal halides for the pre-cleaning agent 432 may include a tungsten fluoride (e.g., WF₆), a tungsten chloride (e.g., WCl₆, WCl₅), a molybdenum chloride (e.g., MoCl₆, MoCl₅), a tantalum chloride (e.g., TaCl₅), and/or a titanium chloride (e.g., TiCl₄), among other examples. In some implementations, the pre-cleaning agent 432 includes a metal precursor of the material of the source/drain contact structure 122. In some implementations, the pre-cleaning agent 432 includes a metal precursor of the material of the source/drain interconnect structure 134. In these implementations, the pre-cleaning operation may be performed as part of depositing the source/drain interconnect structure 134, which reduces the process complexity of manufacturing the semiconductor device 100.

As further shown in FIG. 4F, in some implementations, the pre-cleaning operation may result in formation of the recess 140 in the top surface of the source/drain contact structure 122. This may occur, for example, where the pre-cleaning agent 432 used in the pre-cleaning operation removes metal and oxygen constituents from the metal-oxide layer 406, and the metal constituent corresponds to the metal of the source/drain contact structure 122. Therefore, removal of the metal-oxide layer 406 using the pre-cleaning agent 432 may result in removal of metal from the top surface of the source/drain contact structure 122.

Alternatively, a pre-cleaning agent 432 selected for the pre-cleaning operation may minimally remove metal from the source/drain contact structure 122. In these implementations, the top surface of the source/drain contact structure 122 may be substantially flat after the pre-cleaning operation.

As shown in FIG. 4G, the material of a source/drain interconnect structure 134 may be deposited on the top surface of the source/drain contact structure 122 in the recess 402. The material of the source/drain interconnect structure 134 fills in the recess 402 and contacts the oxide regions 138 on the ends of the ESL 128. A deposition tool (e.g., the same deposition tool, using the same processing chamber, that was used to perform the pre-clean operation) may be used to deposit the material of the source/drain interconnect structure 134 using a CVD technique, and ALD technique, a PVD technique, an electroplating technique, and/or another suitable deposition technique.

A metal precursor may be used to deposit the material of the source/drain interconnect structure 134. The metal precursor may be the same metal precursor that was used as the pre-cleaning agent 432 for the pre-cleaning operation, or may be a different metal precursor. The metal precursor used to deposit the material of the source/drain interconnect structure 134 may selectively deposit on metals such as the top surface of the source/drain contact structure 122. This enables the material of the source/drain interconnect structure 134 to be deposited in a “bottom-up” type of material growth, where the material of the source/drain interconnect structure 134 builds up on the top surface of the source/drain contact structure 122 and not on the sidewalls of the recess 402 corresponding to the ILD layer 126 and the ESL 128. The bottom-up type of material growth for the source/drain interconnect structure 134 reduces the likelihood of formation of voids in the source/drain interconnect structure 134.

In some implementations, the source/drain interconnect structure 134 is formed of tungsten (W), and a tungsten precursor used to deposit the material of the source/drain interconnect structure 134. For example, the tungsten precursor may be a tungsten fluoride (WFₓ) (e.g., a tungsten fluoride gas) such as tungsten hexafluoride (WF₆). As another example, the tungsten precursor may be a tungsten chloride (WClₓ) (e.g., a tungsten chloride gas, a tungsten chloride liquid) such as tungsten hexachloride (WCl₆). The deposition of the material of the source/drain interconnect structure 134 using the tungsten precursor may be performed at a temperature in the processing chamber of the deposition tool that is included in a range of approximately 200 degrees Celsius to approximately 450 degrees Celsius. However, other values and ranges are within the scope of the present disclosure. Additionally and/or alternatively, the deposition of the material of the source/drain interconnect structure 134 using the tungsten precursor may be performed at a pressure in the processing chamber that is included in a range of approximately 0.1 torr to approximately 50 torr. However, other values and ranges are within the scope of the present disclosure. In some implementations, the tungsten precursor may be used with or without a treatment gas such as a hydrogen (H₂) gas and/or an ammonia (NH₃) gas, among other examples.

In some implementations, the source/drain interconnect structure 134 is formed of molybdenum (Mo), and a molybdenum precursor used to deposit the material of the source/drain interconnect structure 134. For example, the molybdenum precursor may be a molybdenum fluoride (MoFₓ) (e.g., a molybdenum fluoride gas) such as molybdenum hexafluoride (MoF₆). The deposition of the material of the source/drain interconnect structure 134 using the molybdenum fluoride as a precursor may be performed at a temperature in the processing chamber of the deposition tool that is included in a range of approximately 200 degrees Celsius to approximately 450 degrees Celsius. However, other values and ranges are within the scope of the present disclosure. In some implementations, the deposition of the material of the source/drain interconnect structure 134 using the molybdenum fluoride as a precursor may be performed at a pressure in the processing chamber that is included in a range of approximately 0.1 torr to approximately 260 torr. However, other values and ranges are within the scope of the present disclosure. In some implementations, the molybdenum fluoride may be used with or without a treatment gas such as a hydrogen (H₂) gas, among other examples.

As another example, the molybdenum precursor may be a molybdenum chloride (MoClₓ) (e.g., a molybdenum chloride gas, a molybdenum chloride liquid) such as molybdenum pentachloride (MoCl₅). The deposition of the material of the source/drain interconnect structure 134 using the molybdenum chloride as a precursor may be performed at a temperature in the processing chamber of the deposition tool that is included in a range of approximately 300 degrees Celsius to approximately 450 degrees Celsius. However, other values and ranges are within the scope of the present disclosure. In some implementations, the deposition of the material of the source/drain interconnect structure 134 using the molybdenum chloride as a precursor may be performed at a pressure in the processing chamber that is included in a range of approximately 0.1 torr to approximately 300 torr. However, other values and ranges are within the scope of the present disclosure. In some implementations, the molybdenum chloride may be used with or without a treatment gas such as a hydrogen (H₂) gas, among other examples.

In some implementations, the source/drain interconnect structure 134 is formed of ruthenium (Ru) and a ruthenium precursor used to deposit the material of the source/drain interconnect structure 134. For example, the ruthenium precursor may be a ruthenium oxide (RuOₓ such as RuO₂). The deposition of the material of the source/drain interconnect structure 134 using the ruthenium oxide as a precursor may be performed at a temperature in the processing chamber of the deposition tool that is included in a range of approximately 200 degrees Celsius to approximately 450 degrees Celsius. However, other values and ranges are within the scope of the present disclosure. In some implementations, the deposition of the material of the source/drain interconnect structure 134 using the ruthenium oxide as a precursor may be performed at a pressure in the processing chamber that is included in a range of approximately 0.1 torr to approximately 260 torr. However, other values and ranges are within the scope of the present disclosure. In some implementations, the ruthenium precursor may be used with or without a treatment gas such as a hydrogen (H₂) gas, among other examples.

In some implementations, the source/drain interconnect structure 134 is formed of cobalt (Co) and a cobalt precursor used to deposit the material of the source/drain interconnect structure 134. For example, the cobalt precursor may be a cobalt chloride (CoClₓ such as CoCl₂), a combination of a cobalt sulfate (CoSₓ) and a cobalt oxide (CoO_{y}), and/or another cobalt precursor. In some implementations, the cobalt precursor may be used with or without a treatment such as Dimethylamine borane (DMAB), ammonium chloride (NH₄Cl), and/or a boron hydroxide (BOₓH_{y}), among other examples. In some implementations, the pH of the treatment chemical may be included in a range of approximately 6 to approximately 9. However, other values and ranges are within the scope of the present disclosure.

In some implementations, the source/drain interconnect structure 134 is formed of copper (Cu) and a copper precursor used to deposit the material of the source/drain interconnect structure 134. For example, the cobalt precursor may be a copper chloride (CuClₓ such as CuCl₂), a combination of a copper sulfate (CuSₓ) and a copper oxide (CuO_{y}), and/or another copper precursor. In some implementations, the copper precursor may be used with or without a treatment such as a cobalt/carbon/hydrogen/nitrogen compound (CoCₓH_{y}N_{z}) and/or a carbon hydroxide (CHₓO_{y}), among other examples. In some implementations, the pH of the treatment chemical may be included in a range of approximately 7 to approximately 10. However, other values and ranges are within the scope of the present disclosure.

As shown in FIG. 4H, a planarization tool may be used to perform a planarization operation (e.g., a CMP operation) to planarize the source/drain interconnect structure 134. In this way, the top surface of the source/drain interconnect structure 134 may be substantially coplanar with the top surface of the ILD layer 126.

As indicated above, FIGS. 4A-4H are provided as an example. Other examples may differ from what is described with regard to FIGS. 4A-4H.

FIGS. 5A-5H are diagrams of an example implementation 500 of forming a gate interconnect structure 136 described herein. In some implementations, one or more of the semiconductor processing operations described in connection with FIGS. 5A-5H may be performed using one or more semiconductor processing tools, such as a deposition tool, an exposure tool, a developer tool, an etch tool, a planarization tool, an ion implantation tool, a plasma tool (e.g., the semiconductor processing tool 408), a wafer/die transport tool, and/or another type of semiconductor processing tool. In some implementations, one or more of the semiconductor processing operations described in connection with FIGS. 5A-5H may be performed as part of the process for forming the semiconductor device 100 illustrated and described in connection with FIGS. 3A-3E.

As shown in FIG. 5A, a gate structure 116 of an integrated circuit device 110 may be formed in the dielectric layer 108 (e.g., as part of a replacement gate process described in connection with FIGS. 3A-3E). The ESL 128 may be formed over and/or on the dielectric layer 108, and over and/or on the gate structure 116 such that the ESL 128 covers the top surface of the gate structure 116.

As further shown in FIG. 5A, the operations described in connection with forming the gate interconnect structure 136 may be performed after forming a source/drain contact structure 122 of the semiconductor device 100. Alternatively, the operations described in connection with forming the gate interconnect structure 136 may be performed prior to forming a source/drain contact structure 122 of the semiconductor device 100.

As shown in FIG. 5B, a recess 502 is formed through the ILD layer 126 and through the ESL 128. The recess 502 is formed over the gate structure 116 so that the top surface of the gate structure 116 is exposed in the recess 502.

In some implementations, a pattern in a photoresist layer is used to etch the ILD layer 126 and/or the ESL 128 to form the recess 502. In these implementations, a deposition tool may be used to form the photoresist layer on the ILD layer 126 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern.

An etch tool may be used to etch the ILD layer 126 and/or the ESL 128 based on the pattern using an etchant 504 to form the recess 502. The etch operation includes the use of an etchant 504 to etch the ILD layer 126 and the ESL 128 to form the recess 502. In some implementations, the etch operation is a dry etch operation, and the etchant 504 is a plasma-based etchant 504 and/or a gas-based etchant 504. In some implementations, the etch operation is a wet etch operation, and the etchant 504 is a wet chemical etchant 504.

In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recess 502 based on a pattern.

As shown in FIG. 5C, a metal-oxide layer 506 may form on the top surface of the gate structure 116 in the recess 502. The metal-oxide layer 506 may be referred to as a “native oxide” in that the metal-oxide layer 506 naturally forms due to oxidation of the top surface of the gate structure 116. The top surface of the gate structure 116 may oxidize due to exposure to various oxygen sources, such as oxygen in the atmosphere in the processing chamber of the etch tool, oxygen in the atmosphere in a semiconductor manufacturing facility in which the semiconductor device 100 is manufactured, and/or from another oxygen source. In some implementations, the top surface of the gate structure 116 may oxidize due to exposure to oxygen while being queued for the next processing step for the semiconductor device 100.

The metal-oxide layer 506 may correspond to a portion of the top surface of the gate structure 116 to which atmospheric oxygen has bonded. Thus, the metal-oxide layer 506 contains a metal of the gate structure 116 and extends below the ESL 128. For example, if the gate structure 116 includes tungsten (W), the metal-oxide layer 506 may include oxidized tungsten (or a tungsten oxide (WOₓ such as WO₃)). As another example, if the gate structure 116 includes molybdenum (Mo), the metal-oxide layer 506 may include oxidized molybdenum (or a molybdenum oxide (MoOₓ such as MoO₃)).

As shown in FIGS. 5D and 5E, an oxidation treatment operation may be performed on the ends of the ESL 128 exposed in the recess 502. The oxidation treatment operation may be performed in order to form the oxide regions 138 in and/or on the exposed ends of the ESL 128. The oxide regions 138 correspond to oxidized portions of the ESL 128 having an oxygen concentration that is greater than the oxygen concentration in other portions of the ESL 128.

As shown in FIG. 5D, the oxidation treatment operation may be performed using the semiconductor processing tool 408. To perform the oxidation treatment operation, the semiconductor device 100 (e.g., on the semiconductor substrate) may be received on the chuck 424 in the processing chamber 410 of the semiconductor processing tool 408, as shown in FIG. 5D. The semiconductor processing tool 408 may be operated to strike a plasma in the processing chamber 410 and/or external to the processing chamber 410 and provided into the processing chamber through the inlet 418. The plasma may be an oxygen-based plasma that is generated from a process gas such as an oxygen (O₂) gas, water vapor (H₂O), a nitrous oxide (NOₓ, where ₓ ranges from 1 to 3 for example) gas, and/or ozone (O₃) gas, among other examples. In some implementations, other process gasses (e.g., carrier gasses, plasma reactant gasses), such as hydrogen (H₂), nitrogen (N₂), and/or argon (Ar) are provided into the processing chamber 410 for the oxidation treatment operation.

As shown in FIG. 5E, the plasma and process gasses in the processing chamber 410 are used as a reactant 508 that is provided into the recess 502 to treat the ends of the ESL 128 that are exposed in the recess 502. The RF source 428 may be used to apply an RF bias to the chuck 424 to promote the flow of the reactant 508 into the recess 502. In some implementations, the frequency of the RF bias is included in a range of approximately 2 megahertz to approximately 10 gigahertz to promote the flow of the reactant 508 into the recess 502. However, other values and/or ranges are within the scope of the present disclosure. The power level of the RF bias may be included in a range of approximately 0.1 watt to approximately 10 kilowatts. However, other values and/or ranges are within the scope of the present disclosure. Additionally and/or alternatively, a pump may be used to pump the processing chamber 410 to at least a partial vacuum such that the pressure in the processing chamber 410 is included in a range of approximately 0.1 millitorr to approximately 30 torr to promote the flow of the reactant 508 into the recess 502. However, other values and/or ranges are within the scope of the present disclosure.

During the oxidation treatment operation, the reactant 508 reacts with the material of the ends of the ESL 128 so that oxygen atoms from the reactant 508 diffuses into the ends of the ESL 128 exposed in the recess 502. Thus, the ends of the ESL 128 after the oxidation treatment operation may contain a combination of silicon (Si), nitrogen (N), and oxygen (O). The diffused oxygen in the ends of the ESL 128 increases the oxygen concentration in the ends of the ESL 128. As a result, the ends of the ESL 128 may have an oxygen concentration that is greater than a nitrogen (N) concentration of the ends of the ESL 128.

The increased oxygen concentration in the oxide regions 138 in and/or on ends of the ESL 128 reduces the dielectric constant of ends of the ESL 128 and increases the band gap of the ends of the ESL 128. For example, the ESL 128 may be formed of silicon nitride (SiₓN_{y}) having a dielectric constant of approximately 8 to approximately 10 and a band gap of approximately 4.55 electron volts to approximately 5.80 electron volts. The oxidation treatment operation may lower the dielectric constant of the ends of the ESL 128 (corresponding to the oxide regions 138) to approximately 3.9, and may increase the band gap of the ends of the ESL 128 (corresponding to the oxide regions 138) to approximately 9 electron volts.

The oxygen from the reactant 508 also deposits onto the ends of the ESL 128, resulting in lateral growth of the ends of the ESL 128. In other words, a portion of an end of the ESL 128 is consumed to form a portion of an oxide region 138, and a second portion of the oxide region grows on the first portion. Thus, the oxide regions 138 may be formed in and on the ends of the ESL 128. As a result of the partial growth of the ends of the ESL 128, portions of the oxide regions 138 may laterally extend over the top surface of the source/drain contact structure 122 that is exposed in the recess 502, and other portions of the oxide regions 138 may laterally extend over the top surface of the underlying dielectric layer 108.

In some implementations, the sidewalls 412, the lid 414, and/or the chamber floor 416 of the processing chamber 410 may be formed of one or more materials that resists damage to the sidewalls 412, the lid 414, and/or the chamber floor 416 during the oxidation treatment operation. For example, the material of the sidewalls 412 may include a metal-oxide material and/or a ceramic material that resists damage to the sidewalls 412 during the oxidation treatment operation. As another example, the material of the lid 414 may include a metal-oxide material and/or a ceramic material that resists damage to the lid 414 during the oxidation treatment operation. As another example, the material of the chamber floor 416 may include a metal-oxide material and/or a ceramic material that resists damage to the chamber floor 416 during the oxidation treatment operation. Such materials may include, for example, a zirconium oxide material (ZrOₓ), an aluminum oxide material (AlₓO_{y}), an yttrium (Y)-containing ceramic, an aluminum (Al)-containing ceramic, and/or a chromium (Cr)-containing ceramic.

In some implementations, the sidewalls 412, the lid 414, and/or the chamber floor 416 of the processing chamber 410 may be covered with a coating material that resists damage to the sidewalls 412, the lid 414, and/or the chamber floor 416 during the oxidation treatment operation. For example, the sidewalls 412 may be coated with a coating material that resists damage to the sidewalls 412 during the oxidation treatment operation. As another example, the lid 414 may be coated with a coating material that resists damage to the lid 414 during the oxidation treatment operation. As another example, the chamber floor 416 may be coated with a coating material that resists damage to the chamber floor 416 during the oxidation treatment operation. Such coating materials may include, for example, an alkaline earth fluoride material (e.g., calcium fluoride (CaF₂), magnesium fluoride (MgF₂), strontium fluoride (SrF₂)), a boron nitride (BN) material, a carbide material (e.g., silicon carbide (SiC), tungsten carbide (WC)), and/or a metal pnictide material (e.g., LaOFeAs, Ca₄Sb₂O), among other examples.

As shown in FIG. 5F, a pre-cleaning operation may be performed to remove the metal-oxide layer 506 from the top surface of the gate structure 116. The metal-oxide layer 506 may be removed from the top surface of the gate structure 116 to provide a bare-metal substrate on which a gate interconnect structure 136 is to be formed on the gate structure 116 in the recess 502.

The pre-cleaning operation includes the use of a pre-cleaning agent 510. The pre-cleaning agent 510 may include a wet chemical pre-cleaning agent, a dry gas pre-cleaning agent, and/or another type of pre-cleaning agent. The pre-cleaning agent 510 may be provided into the recess 502 (e.g., using the deposition tool or a dedicated pre-cleaning tool) so that the metal-oxide layer 506 is soaked in the pre-cleaning agent 510 for a time duration.

In some implementations, the pre-cleaning operation may be performed prior to the oxidation treatment operation described in connection with FIGS. 5D and 5E. In some implementations, the pre-cleaning operation may be performed after the oxidation treatment operation described in connection with FIGS. 5D and 5E so that additional metal-oxide material formed during the oxidation treatment operation can be removed during the pre-cleaning operation.

In some implementations, the pre-cleaning operation is performed as part of the oxidation treatment operation described in connection with FIGS. 5D and 5E. In these implementations, the pre-cleaning agent 510 corresponds to the reactant 508. Thus, the reactant 508 may be used to oxidize the ends of the ESL 128 as well as remove the metal-oxide layer 506 during the same operation.

In some implementations, the pre-cleaning agent 510 may include a metal precursor that etches or removes material from the metal-oxide layer 506. For example, the pre-cleaning agent 510 may include a halogen-based metal precursor, such as a transition metal halide. Examples of transition metal halides for the pre-cleaning agent 510 may include a tungsten fluoride (e.g., WF₆), a tungsten chloride (e.g., WCl₆, WCl₅), a molybdenum chloride (e.g., MoCl₆, MoCl₅), a tantalum chloride (e.g., TaCl₅), and/or a titanium chloride (e.g., TiCl₄), among other examples. In some implementations, the pre-cleaning agent 510 includes a metal precursor of the material of the gate structure 116. In some implementations, the pre-cleaning agent 510 includes a metal precursor of the material of the gate interconnect structure 136. In these implementations, the pre-cleaning operation may be performed as part of depositing the gate interconnect structure 136, which reduces the process complexity of manufacturing the semiconductor device 100.

As shown in FIG. 5G, the material of a gate interconnect structure 136 may be deposited on the top surface of the gate structure 116 in the recess 502. The material of the gate interconnect structure 136 fills in the recess 502 and contacts the oxide regions 138 on the ends of the ESL 128. A deposition tool (e.g., the same deposition tool, using the same processing chamber, that was used to perform the pre-clean operation) may be used to deposit the material of the gate interconnect structure 136 using a CVD technique, and ALD technique, a PVD technique, an electroplating technique, and/or another suitable deposition technique.

A metal precursor may be used to deposit the material of the gate interconnect structure 136. The metal precursor may be the same metal precursor that was used as the pre-cleaning agent 510 for the pre-cleaning operation, or may be a different metal precursor. The metal precursor used to deposit the material of the gate interconnect structure 136 may selectively deposit on metals such as the top surface of the gate structure 116. This enables the material of the gate interconnect structure 136 to be deposited in a “bottom-up” type of material growth, where the material of the gate interconnect structure 136 builds up on the top surface of the gate structure 116 and not on the sidewalls of the recess 502 corresponding to the ILD layer 126 and the ESL 128. The bottom-up type of material growth for the gate interconnect structure 136 reduces the likelihood of formation of voids in the gate interconnect structure 136.

In some implementations, the gate interconnect structure 136 is formed of tungsten (W), and a tungsten precursor used to deposit the material of the gate interconnect structure 136. For example, the tungsten precursor may be a tungsten fluoride (WFₓ) (e.g., a tungsten fluoride gas) such as tungsten hexafluoride (WF₆). As another example, the tungsten precursor may be a tungsten chloride (WClₓ) (e.g., a tungsten chloride gas, a tungsten chloride liquid) such as tungsten hexachloride (WCl₆). The deposition of the material of the gate interconnect structure 136 using the tungsten precursor may be performed at a temperature in the processing chamber of the deposition tool that is included in a range of approximately 200 degrees Celsius to approximately 450 degrees Celsius. However, other values and ranges are within the scope of the present disclosure. Additionally and/or alternatively, the deposition of the material of the gate interconnect structure 136 using the tungsten precursor may be performed at a pressure in the processing chamber that is included in a range of approximately 0.1 torr to approximately 50 torr. However, other values and ranges are within the scope of the present disclosure. In some implementations, the tungsten precursor may be used with or without a treatment gas such as a hydrogen (H₂) gas and/or an ammonia (NH₃) gas, among other examples.

In some implementations, the gate interconnect structure 136 is formed of molybdenum (Mo), and a molybdenum precursor used to deposit the material of the gate interconnect structure 136. For example, the molybdenum precursor may be a molybdenum fluoride (MoFₓ) (e.g., a molybdenum fluoride gas) such as molybdenum hexafluoride (MoF₆). The deposition of the material of the gate interconnect structure 136 using the molybdenum fluoride as a precursor may be performed at a temperature in the processing chamber of the deposition tool that is included in a range of approximately 200 degrees Celsius to approximately 450 degrees Celsius. However, other values and ranges are within the scope of the present disclosure. In some implementations, the deposition of the material of the gate interconnect structure 136 using the molybdenum fluoride as a precursor may be performed at a pressure in the processing chamber that is included in a range of approximately 0.1 torr to approximately 260 torr. However, other values and ranges are within the scope of the present disclosure. In some implementations, the molybdenum fluoride may be used with or without a treatment gas such as a hydrogen (H₂) gas, among other examples.

As another example, the molybdenum precursor may be a molybdenum chloride (MoClₓ) (e.g., a molybdenum chloride gas, a molybdenum chloride liquid) such as molybdenum pentachloride (MoCl₅). The deposition of the material of the gate interconnect structure 136 using the molybdenum chloride as a precursor may be performed at a temperature in the processing chamber of the deposition tool that is included in a range of approximately 300 degrees Celsius to approximately 450 degrees Celsius. However, other values and ranges are within the scope of the present disclosure. In some implementations, the deposition of the material of the gate interconnect structure 136 using the molybdenum chloride as a precursor may be performed at a pressure in the processing chamber that is included in a range of approximately 0.1 torr to approximately 300 torr. However, other values and ranges are within the scope of the present disclosure. In some implementations, the molybdenum chloride may be used with or without a treatment gas such as a hydrogen (H₂) gas, among other examples.

In some implementations, the gate interconnect structure 136 is formed of ruthenium (Ru) and a ruthenium precursor used to deposit the material of the gate interconnect structure 136. For example, the ruthenium precursor may be a ruthenium oxide (RuOₓ such as RuO₂). The deposition of the material of the gate interconnect structure 136 using the ruthenium oxide as a precursor may be performed at a temperature in the processing chamber of the deposition tool that is included in a range of approximately 200 degrees Celsius to approximately 450 degrees Celsius. However, other values and ranges are within the scope of the present disclosure. In some implementations, the deposition of the material of the gate interconnect structure 136 using the ruthenium oxide as a precursor may be performed at a pressure in the processing chamber that is included in a range of approximately 0.1 torr to approximately 260 torr. However, other values and ranges are within the scope of the present disclosure. In some implementations, the ruthenium precursor may be used with or without a treatment gas such as a hydrogen (H₂) gas, among other examples.

In some implementations, the gate interconnect structure 136 is formed of cobalt (Co) and a cobalt precursor used to deposit the material of the gate interconnect structure 136. For example, the cobalt precursor may be a cobalt chloride (CoClₓ such as CoCl₂), a combination of a cobalt sulfate (CoSₓ) and a cobalt oxide (CoO_{y}), and/or another cobalt precursor. In some implementations, the cobalt precursor may be used with or without a treatment such as Dimethylamine borane (DMAB), ammonium chloride (NH₄Cl), and/or a boron hydroxide (BOₓH_{y}), among other examples. In some implementations, the pH of the treatment chemical may be included in a range of approximately 6 to approximately 9. However, other values and ranges are within the scope of the present disclosure.

In some implementations, the gate interconnect structure 136 is formed of copper (Cu) and a copper precursor used to deposit the material of the gate interconnect structure 136. For example, the copper precursor may be a copper chloride (CuClₓ such as CuCl₂), a combination of a copper sulfate (CuSₓ) and a copper oxide (CuSₓ), and/or another copper precursor. In some implementations, the cobalt precursor may be used with or without a treatment such as a cobalt/carbon/hydrogen/nitrogen compound (CoCₓH_{y}N_{z}) and/or a carbon hydroxide (CHₓO_{y}), among other examples. In some implementations, the pH of the treatment chemical may be included in a range of approximately 7 to approximately 10. However, other values and ranges are within the scope of the present disclosure.

As shown in FIG. 5H, a planarization tool may be used to perform a planarization operation (e.g., a CMP operation) to planarize the gate interconnect structure 136. In this way, the top surface of the gate interconnect structure 136 may be substantially coplanar with the top surface of the ILD layer 126.

As indicated above, FIGS. 5A-5H are provided as an example. Other examples may differ from what is described with regard to FIGS. 5A-5H.

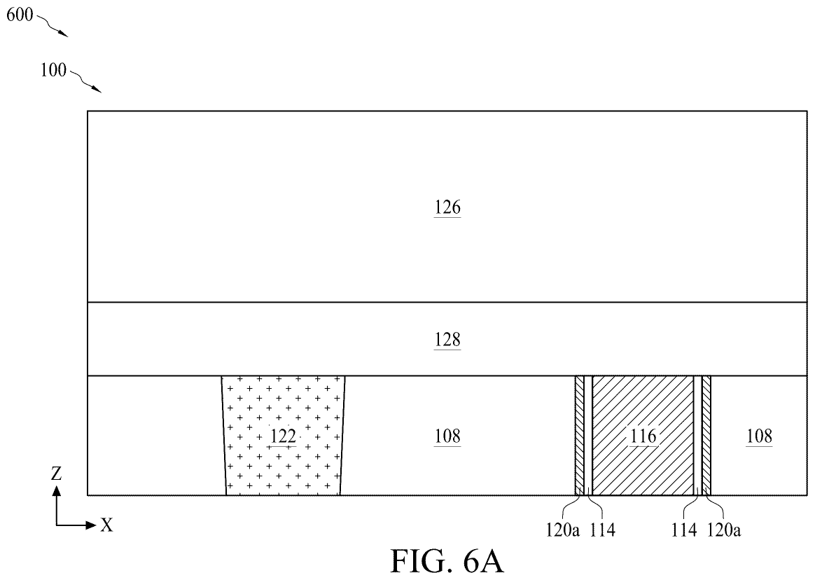

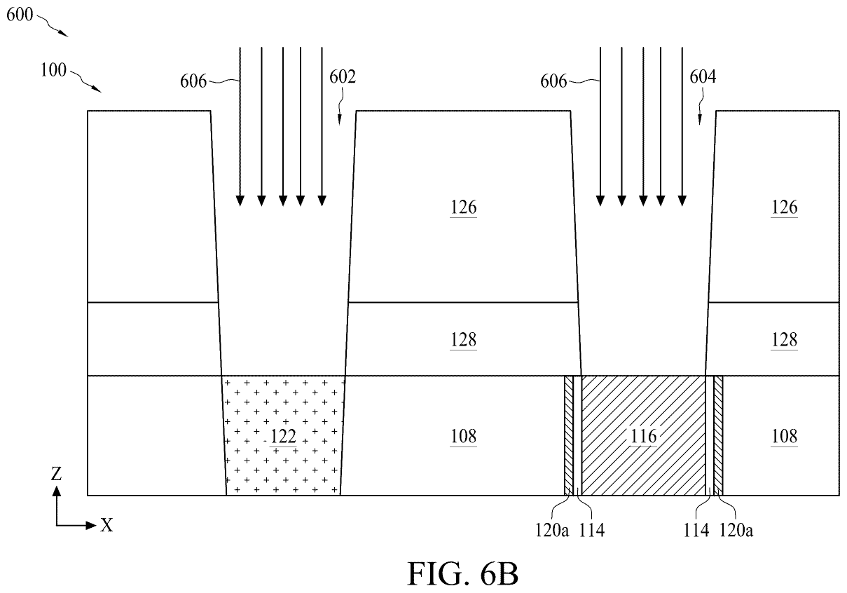

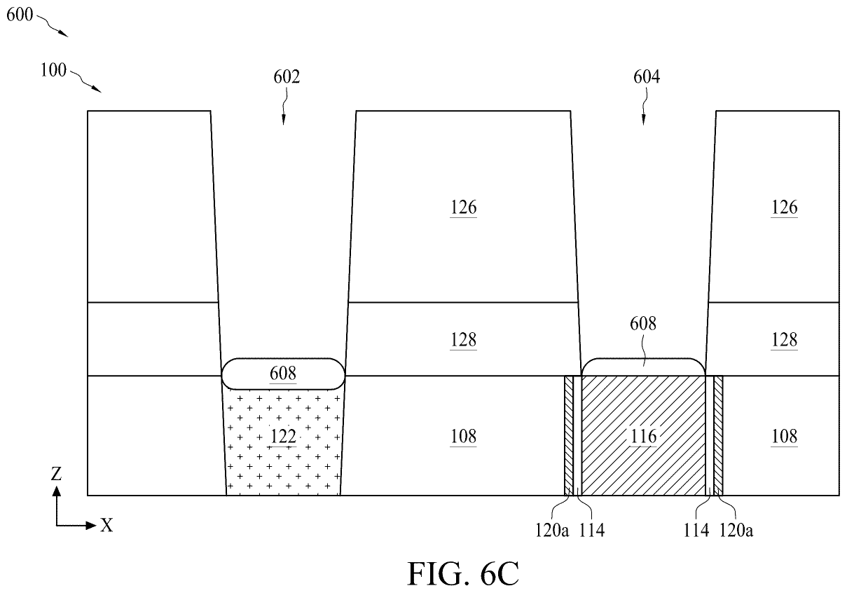

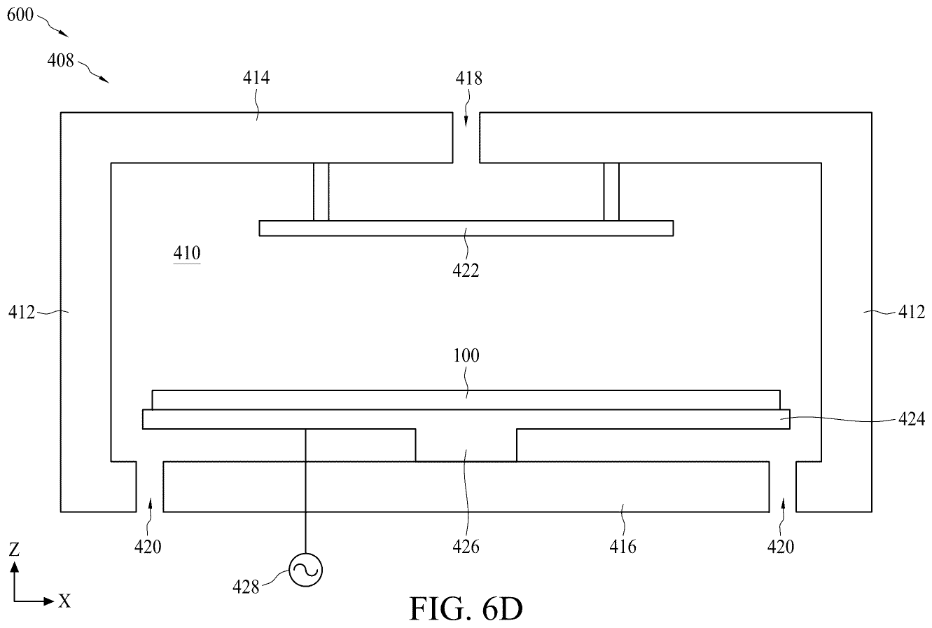

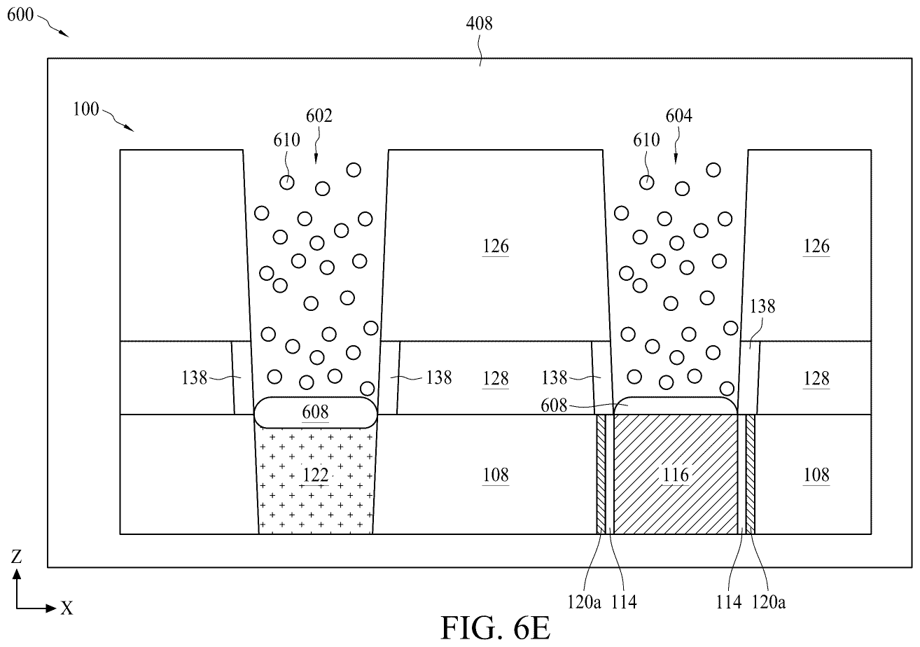

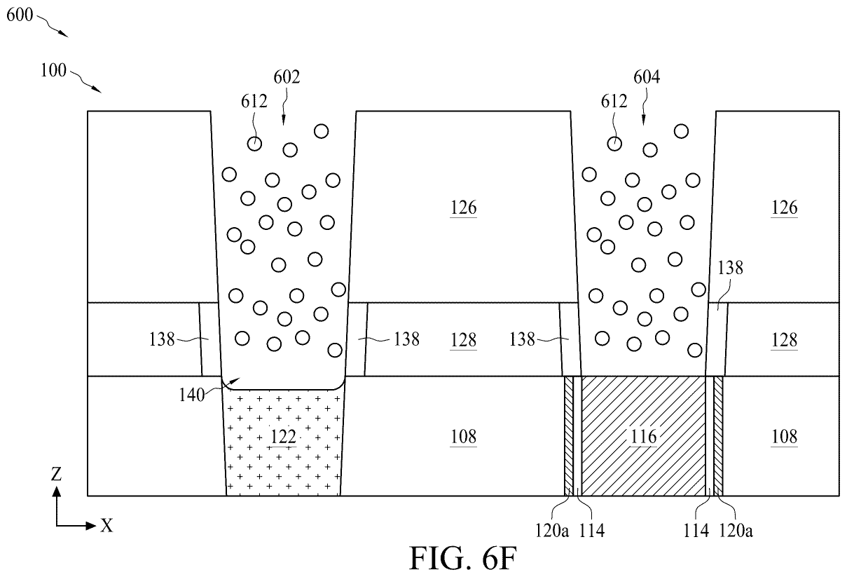

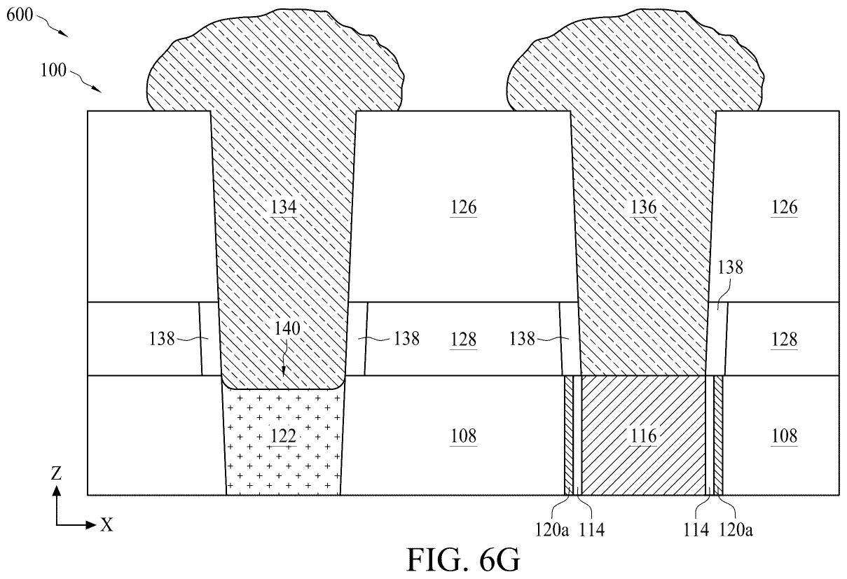

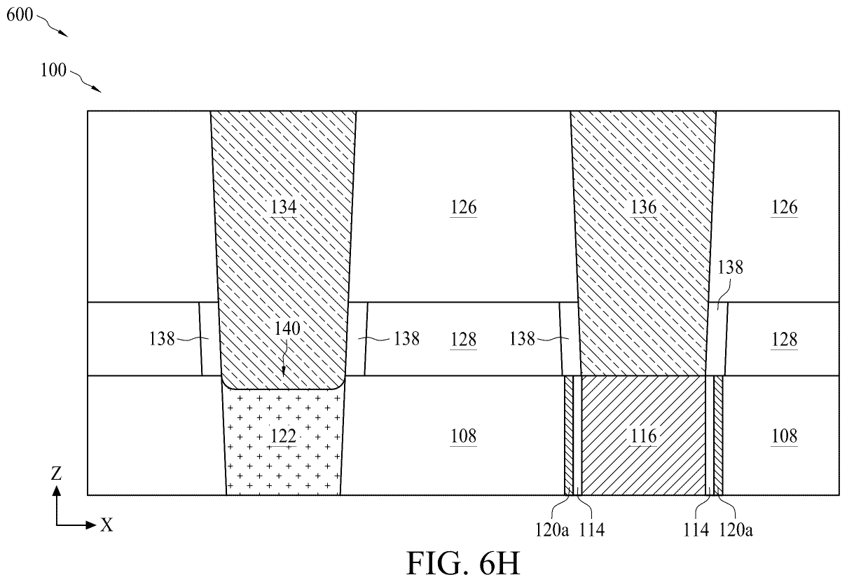

FIGS. 6A-6H are diagrams of an example implementation 600 of forming a source/drain interconnect structure 134 and a gate interconnect structure 136 described herein. In some implementations, one or more of the semiconductor processing operations described in connection with FIGS. 6A-6H may be performed using one or more semiconductor processing tools, such as a deposition tool, an exposure tool, a developer tool, an etch tool, a planarization tool, an ion implantation tool, a plasma tool (e.g., the semiconductor processing tool 408), a wafer/die transport tool, and/or another type of semiconductor processing tool. In some implementations, one or more of the semiconductor processing operations described in connection with FIGS. 6A-6H may be performed as part of the process for forming the semiconductor device 100 illustrated and described in connection with FIGS. 3A-3E.

As shown in FIG. 6A, a gate structure 116 and a source/drain contact structure 122 of an integrated circuit device 110 may be formed in the dielectric layer 108 (e.g., as part of the process of forming the semiconductor device 100 described in connection with FIGS. 3A-3E). The ESL 128 may be formed over and/or on the dielectric layer 108, over and/or on the gate structure 116, and over and/or on the source/drain contact structure 122 such that the ESL 128 covers the top surface of the gate structure 116 and the top surface of the source/drain contact structure 122.

As shown in FIG. 6B, recesses 602 and 604 are formed through the ILD layer 126 and through the ESL 128. The recess 602 is formed over the source/drain contact structure 122 so that the top surface of the source/drain contact structure 122 is exposed in the recess 602. The recess 604 is formed over the gate structure 116 so that the top surface of the gate structure 116 is exposed in the recess 604.

In some implementations, a pattern in a photoresist layer is used to etch the ILD layer 126 and/or the ESL 128 to form the recesses 602 and 604. In these implementations, a deposition tool may be used to form the photoresist layer on the ILD layer 126 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern.

An etch tool may be used to etch the ILD layer 126 and/or the ESL 128 based on the pattern using an etchant 606 to form the recesses 602 and 604. The etch operation includes the use of an etchant 606 to etch the ILD layer 126 and the ESL 128 to form the recesses 602 and 604. In some implementations, the etch operation is a dry etch operation, and the etchant 606 is a plasma-based etchant 606 and/or a gas-based etchant 606. In some implementations, the etch operation is a wet etch operation, and the etchant 606 is a wet chemical etchant 606.

In some implementations, a photoresist removal tool may be used to remove the remaining portions of the photoresist layer (e.g., using a chemical stripper, plasma ashing, and/or another technique). In some implementations, a hard mask layer is used as an alternative technique for forming the recesses 602 and 604 based on a pattern.

As shown in FIG. 6C, a metal-oxide layers 608 may form on the top surface of the source/drain contact structure 122 in the recess 602, and may form on the top surface of the gate structure 116 in the recess 604. A metal-oxide layer 608 may correspond to a portion of the top surface of the source/drain contact structure 122 to which atmospheric oxygen has bonded, and another metal-oxide layer 608 may correspond to a portion of the top surface of the gate structure 116 to which atmospheric oxygen has bonded.

As shown in FIGS. 6D and 6E, an oxidation treatment operation may be performed on the ends of the ESL 128 exposed in the recesses 602 and 604. The oxidation treatment operation may be performed to form the oxide regions 138 in and/or on the exposed ends of the ESL 128 in the recesses 602 and in the recesses 604. The oxide regions 138 correspond to oxidized portions of the ESL 128 having an oxygen concentration that is greater than the oxygen concentration in other portions of the ESL 128.

As shown in FIG. 6D, the oxidation treatment operation may be performed using the semiconductor processing tool 408. To perform the oxidation treatment operation, the semiconductor device 100 (e.g., on the semiconductor substrate) may be received on the chuck 424 in the processing chamber 410 of the semiconductor processing tool 408, as shown in FIG. 6D. The semiconductor processing tool 408 may be operated to strike a plasma in the processing chamber 410 and/or external to the processing chamber 410 and provided into the processing chamber through the inlet 418. The plasma may be an oxygen-based plasma that is generated from a process gas such as an oxygen (O₂) gas, water vapor (H₂O), a nitrous oxide (NOₓ, where ₓ ranges from 1 to 3 for example) gas, and/or ozone (O₃) gas, among other examples. In some implementations, other process gasses (e.g., carrier gasses, plasma reactant gasses), such as hydrogen (H₂), nitrogen (N₂), and/or argon (Ar) are provided into the processing chamber 410 for the oxidation treatment operation.

As shown in FIG. 6E, the plasma and process gasses in the processing chamber 410 are used as a reactant 610 that is provided into the recesses 602 and 604 to treat the ends of the ESL 128 that are exposed in the recesses 602 and 604. The RF source 428 may be used to apply an RF bias to the chuck 424 to promote the flow of the reactant 610 into the recesses 602 and 604. In some implementations, the frequency of the RF bias is included in a range of approximately 2 megahertz to approximately 10 gigahertz to promote the flow of the reactant 610 into the recesses 602 and 604. However, other values and/or ranges are within the scope of the present disclosure. The power level of the RF bias may be included in a range of approximately 0.1 watt to approximately 10 kilowatts. However, other values and/or ranges are within the scope of the present disclosure. Additionally and/or alternatively, a pump may be used to pump the processing chamber 410 to at least a partial vacuum such that the pressure in the processing chamber 410 is included in a range of approximately 0.1 millitorr to approximately 30 torr to promote the flow of the reactant 610 into the recesses 602 and 604. However, other values and/or ranges are within the scope of the present disclosure.

During the oxidation treatment operation, the reactant 610 reacts with the material of the ends of the ESL 128 so that oxygen atoms from the reactant 610 diffuses into the ends of the ESL 128 exposed in the recesses 602 and 604. Thus, the ends of the ESL 128 after the oxidation treatment operation may contain a combination of silicon (Si), nitrogen (N), and oxygen (O). The diffused oxygen in the ends of the ESL 128 increases the oxygen concentration in the ends of the ESL 128. As a result, the ends of the ESL 128 may have an oxygen concentration that is greater than a nitrogen (N) concentration of the ends of the ESL 128.

The increased oxygen concentration in the ends of the ESL 128 reduces the dielectric constant of ends of the ESL 128 and increases the band gap of the ends of the ESL 128. For example, the ESL 128 may be formed of silicon nitride (SiₓN_{y}) having a dielectric constant of approximately 8 to approximately 10 and a band gap of approximately 4.55 electron volts to approximately 5.80 electron volts. The oxidation treatment operation may lower the dielectric constant of the ends of the ESL 128 (corresponding to the oxide regions 138) to approximately 3.9, and may increase the band gap of the ends of the ESL 128 (corresponding to the oxide regions 138) to approximately 9 electron volts.

The oxygen from the reactant 610 may also deposit onto the ends of the ESL 128, resulting in lateral growth of the ends of the ESL 128. In other words, a portion of an end of the ESL 128 is consumed to form a portion of an oxide region 138, and a second portion of the oxide region grows on the first portion. Thus, the oxide regions 138 may be formed in and on the ends of the ESL 128. As a result of the partial growth of the ends of the ESL 128, portions of the oxide regions 138 formed on ends of the ESL 128 exposed in the recess 602 may laterally extend over the top surface of the source/drain contact structure 122 that is exposed in the recess 602, and other portions of the oxide regions 138 formed on ends of the ESL 128 exposed in the recess 602 may laterally extend over the top surface of the underlying dielectric layer 108. Similarly, portions of the oxide regions 138 formed on ends of the ESL 128 exposed in the recess 604 may laterally extend over the top surface of the gate structure 116 that is exposed in the recess 604, and other portions of the oxide regions 138 formed on ends of the ESL 128 exposed in the recess 604 may laterally extend over the top surface of the underlying dielectric layer 108.

As shown in FIG. 6F, a pre-cleaning operation may be performed to remove the metal-oxide layer 608 from the top surface of the gate structure 116 and from the top surface of the source/drain contact structure 122. The pre-cleaning operation includes the use of a pre-cleaning agent 612. In some implementations, the pre-cleaning operation may be performed prior to the oxidation treatment operation described in connection with FIGS. 6D and 6E. In some implementations, the pre-cleaning operation may be performed after the oxidation treatment operation described in connection with FIGS. 6D and 6E so that additional metal-oxide material formed during the oxidation treatment operation can be removed during the pre-cleaning operation.

In some implementations, the pre-cleaning operation is performed as part of the oxidation treatment operation described in connection with FIGS. 6D and 6E. In these implementations, the pre-cleaning agent 612 corresponds to the reactant 610. Thus, the reactant 610 may be used to oxidize the ends of the ESL 128 as well as remove the metal-oxide layer 608 during the same operation.

As shown in FIG. 6G, the material of a source/drain interconnect structure 134 is deposited on the top surface of the source/drain contact structure 122 in the recess 602, and material of a gate interconnect structure 136 is deposited on the top surface of the gate structure 116 in the recess 604. The material of the source/drain interconnect structure 134 fills in the recess 602 and contacts the oxide regions 138 on the ends of the ESL 128. The material of the gate interconnect structure 136 fills in the recess 604 and contacts the oxide regions 138 on the ends of the ESL 128. A deposition tool (e.g., the same deposition tool, using the same processing chamber, that was used to perform the pre-clean operation) may be used to deposit the material of the source/drain interconnect structure 134 and of the gate interconnect structure 136 using a CVD technique, and ALD technique, a PVD technique, an electroplating technique, and/or another suitable deposition technique.

As shown in FIG. 6H, a planarization tool may be used to perform a planarization operation (e.g., a CMP operation) to planarize the source/drain interconnect structure 134 and the gate interconnect structure 136. In this way, the top surface of the source/drain interconnect structure 134, the top surface of the gate interconnect structure 136, and the top surface of the ILD layer 126 may be substantially coplanar.

As indicated above, FIGS. 6A-6H are provided as an example. Other examples may differ from what is described with regard to FIGS. 6A-6H.

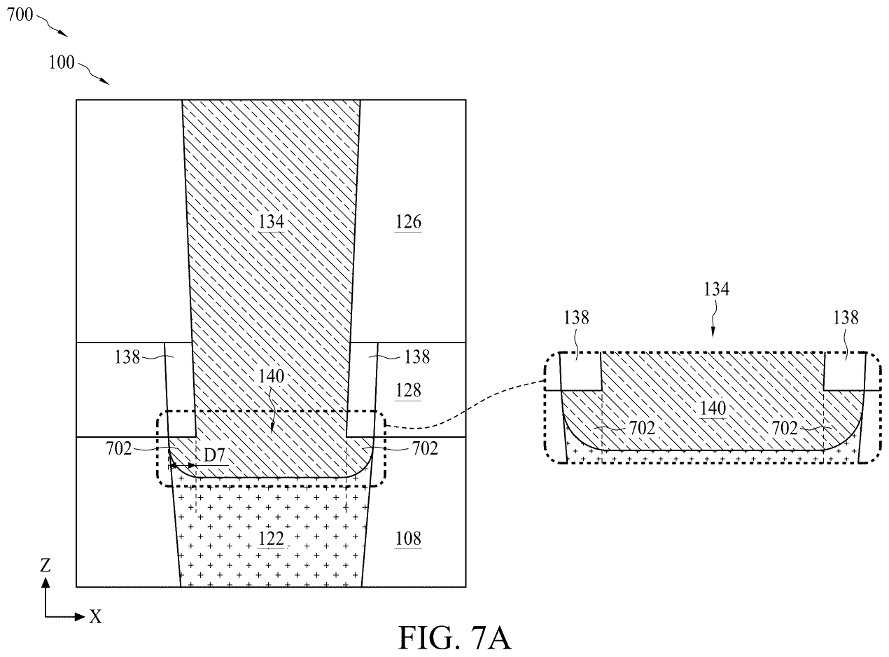

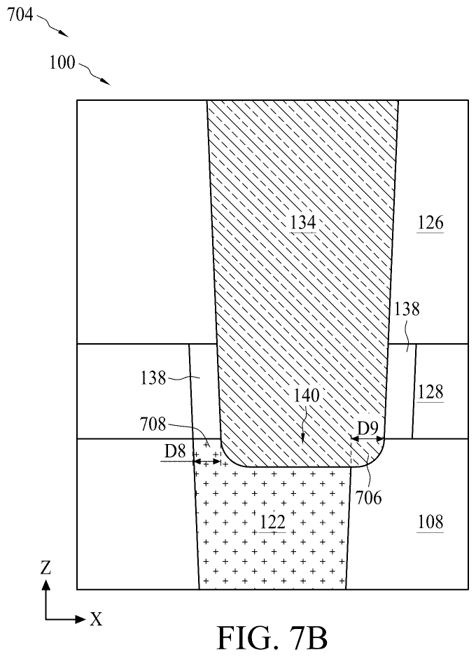

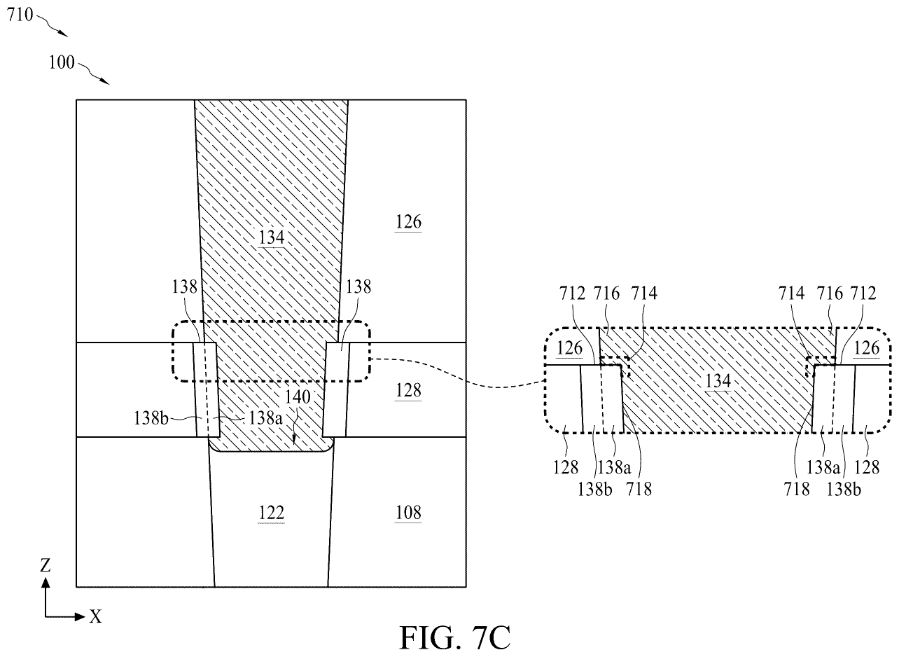

FIGS. 7A-7C are diagrams of example implementations of source/drain contact structures 122 and source/drain interconnect structures 134 for the semiconductor device 100 described herein.

FIG. 7A illustrates an example implementation 700 of a source/drain contact structure 122, a source/drain interconnect structure 134, and oxide regions 138. As shown in FIG. 7A, the source/drain contact structure 122 and the source/drain interconnect structure 134 in the example implementation 700 are similar to the source/drain interconnect structure 134 in the example implementation illustrated in FIG. 1B. However, in the example implementation 700, the bottom portion of the source/drain interconnect structure 134 in the recess 140 of the source/drain contact structure 122 includes extension regions 702 that extend laterally outward past the sidewalls of the source/drain interconnect structure 134. This may occur due to lateral etching in the top surface of the source/drain contact structure 122 during the pre-cleaning operation described in connection with FIGS. 4F and/or 6F. In some implementations, a lateral width (dimension D7) of an extension region 702 may be greater than 0 nanometers and up to approximately 5 nanometers. However, other values and ranges are within the scope of the present disclosure.

As further shown in a close-up view in FIG. 7A, the extension regions 702 may extend under at least a portion of the oxide regions 138. In these implementations, the bottom surfaces of the oxide regions 138 may be in contact with the extension regions 702. Thus, at least two surfaces (e.g., the sidewall facing the source/drain interconnect structure 134 and the bottom surface) of an oxide region 138 may be in contact with the source/drain interconnect structure 134. In some implementations, an extension region 702 extends under a portion of an oxide region 138 such that a portion of the bottom surface of the oxide region 138 is in contact with the extension region 702 of the source/drain interconnect structure 134, and another portion of the bottom surface of the oxide region 138 is in contact with the dielectric layer 108.

FIG. 7B illustrates an example implementation 704 of a source/drain contact structure 122, a source/drain interconnect structure 134, and oxide regions 138. As shown in FIG. 7B, the source/drain contact structure 122 and the source/drain interconnect structure 134 in the example implementation 704 are similar to the source/drain interconnect structure 134 in the example implementation illustrated in FIG. 1B. However, in the example implementation 704, the source/drain interconnect structure 134 and the source/drain contact structure 122 may be partially offset from each other in the x-direction and/or in a y-direction in the semiconductor device 100. The partial offset may occur due to overlay misalignment when forming the recess (e.g., the recess 402, the recess 602) for the source/drain interconnect structure 134. Thus, the bottom surface of source/drain interconnect structure 134 formed in the recess may be laterally shifted relative to the top surface of the source/drain contact structure 122.

This may result in a portion 706 of the bottom surface of the source/drain interconnect structure 134 being in contact with the dielectric layer 108, and/or may result in a portion 708 of the top surface of the source/drain contact structure 122 being in contact with an oxide region 138 and/or with the ESL 128. Accordingly, the bottom surface of a first oxide region 138 may be in contact with the top surface of the source/drain contact structure 122, and the bottom surface of a second oxide region 138 (e.g., on an opposing side of the source/drain interconnect structure 134) may be in contact with the top surface of the dielectric layer 108.

In some implementations, a lateral size (dimension D8) of the portion 708 may be included in a range of approximately 0 nanometers to approximately 3 nanometers. However, other values and ranges are within the scope of the present disclosure. In some implementations, a lateral size (dimension D9) of the portion 706 may be included in a range of approximately 0 nanometers to approximately 3 nanometers. However, other values and ranges are within the scope of the present disclosure.

FIG. 7C illustrates an example implementation 710 of a source/drain contact structure 122, a source/drain interconnect structure 134, and oxide regions 138. As shown in FIG. 7C, the source/drain contact structure 122 and the source/drain interconnect structure 134 in the example implementation 710 are similar to the source/drain interconnect structure 134 in the example implementation illustrated in FIG. 1B. However, in the example implementation 710, the oxide regions 138 laterally extend into the source/drain interconnect structure 134. As a result, a top surface 712 of a portion 138a of an oxide region 138 is in contact with a stair-stepped segment 714 of the source/drain interconnect structure 134, and the top surface 712 of another portion 138b of the oxide region 138 is in contact with the ILD layer 126. In some implementations, the bottom surface of the portion 138a of the oxide region 138 is in contact with the source/drain interconnect structure 134, and the bottom surface of the portion 138b of the oxide region 138 is in contact with the dielectric layer 108.

The stair-stepped segments 714 of the source/drain interconnect structure 134 occur because of the lateral expansion of the oxide regions 138 during the oxidation treatment to form the oxide regions 138 from the ESL 128. Material of the oxide regions 138 may laterally grow outward into the recess in which the source/drain interconnect structure 134 was formed, resulting in the sidewalls of the source/drain interconnect structure 134 conforming to the lateral extension of the oxide regions 138.

A stair-stepped segment 714 may provide a transition between a segment 716 of a sidewall of the source/drain interconnect structure 134 and a segment 718 of the sidewall of the source/drain interconnect structure 134. The segment 716 may be in contact with the ILD layer 126, and the segment 718 may be in contact with the sidewall of the oxide region 138.

As indicated above, FIGS. 7A-7C are provided as examples. Other examples may differ from what is described with regard to FIGS. 7A-7C.

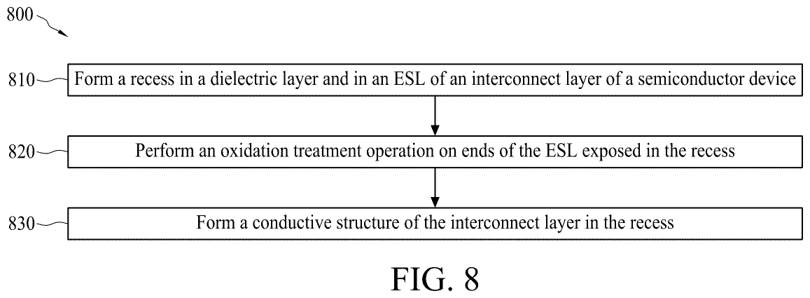

FIG. 8 is a flowchart of an example process 800 associated with forming a semiconductor device described herein. In some implementations, one or more process blocks of FIG. 8 are performed using one or more semiconductor processing tools, such as a deposition tool, an exposure tool, a developer tool, an etch tool, a planarization tool, an ion implantation tool, an annealing tool, a plasma tool, a wafer/die transport tool, and/or another type of semiconductor processing tool.

As shown in FIG. 8, process 800 may include forming a recess in a dielectric layer and in an ESL of an interconnect layer of a semiconductor device (block 810). For example, one or more semiconductor processing tools may be used to form a recess (e.g., a recess 402, a recess 502, a recess 602, a recess 604) in a dielectric layer (e.g., an ILD layer 126) and in an ESL (e.g., an ESL 128) of an interconnect layer (e.g., an interconnect layer 104) of a semiconductor device (e.g., a semiconductor device 100), as described herein. In some implementations, the dielectric layer is above the ESL. In some implementations, the ESL is above a contact structure (e.g., a source/drain contact structure 122) and a gate structure (e.g., a gate structure 116) of an integrated circuit device (e.g., an integrated circuit device 110) in a device layer (e.g., a device layer 102) of the semiconductor device.

As further shown in FIG. 8, process 800 may include performing an oxidation treatment operation on ends of the ESL exposed in the recess (block 820). For example, one or more semiconductor processing tools may be used to perform an oxidation treatment operation on ends of the ESL exposed in the recess, as described herein. In some implementations, the oxidation treatment operation results in formation of a oxide regions (e.g., oxide regions 138) on the ends of the ESL. In some implementations, a first material of the oxide regions and a second material of the ESL are different materials that have different band gaps.

As further shown in FIG. 8, process 800 may include forming a conductive structure of the interconnect layer in the recess (block 830). For example, one or more semiconductor processing tools may be used to form a conductive structure (e.g., a source/drain interconnect structure 134, a gate interconnect structure 136) of the interconnect layer in the recess, as described herein.

Process 800 may include additional implementations, such as any single implementation or any combination of implementations described below and/or in connection with one or more other processes described elsewhere herein.

In a first implementation, performing the oxidation treatment operation includes performing the oxidation treatment operation using an oxygen-containing reactant (e.g., a reactant 430, a reactant 508, a reactant 610) that includes an oxygen-containing plasma.

In a second implementation, alone or in combination with the first implementation, performing the oxidation treatment operation includes performing the oxidation treatment operation using an oxygen-containing reactant (e.g., a reactant 430, a reactant 508, a reactant 610) that includes an oxygen-containing gas.

In a third implementation, alone or in combination with one or more of the first and second implementations, the oxygen-containing gas includes at least one of oxygen (O₂), nitrous oxide (NOₓ), water vapor (H₂O), or ozone (O₃).

In a fourth implementation, alone or in combination with one or more of the first through third implementations, performing the oxidation treatment operation includes performing the oxidation treatment operation using a hydrogen (H₂) gas.

In a fifth implementation, alone or in combination with one or more of the first through fourth implementations, a portion of the ends of the ESL is consumed to form a first portion of an oxide region of the oxide regions, and a second portion of the oxide region grows on the first portion.

In a sixth implementation, alone or in combination with one or more of the first through fifth implementations, forming the recess includes forming the recess such that a top surface of the contact structure is exposed through the recess, and forming the conductive structure includes forming a source/drain interconnect structure (e.g., a source/drain interconnect structure 134) in the recess on the contact structure.

In a seventh implementation, alone or in combination with one or more of the first through sixth implementations, forming the recess includes forming the recess such that a top surface of the gate structure is exposed through the recess, and forming the conductive structure includes forming a gate interconnect structure (e.g., a gate interconnect structure 136) in the recess on the gate structure.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

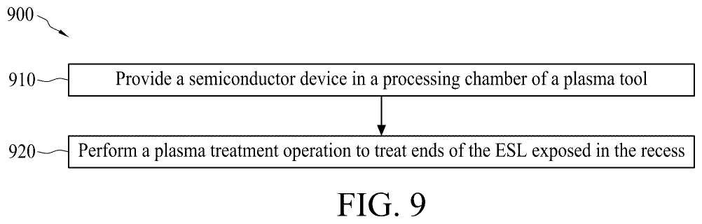

FIG. 9 is a flowchart of an example process 900 associated with forming a semiconductor device described herein. In some implementations, one or more process blocks of FIG. 9 are performed using one or more semiconductor processing tools, such as a deposition tool, an exposure tool, a developer tool, an etch tool, a planarization tool, an ion implantation tool, an annealing tool, a plasma tool, a wafer/die transport tool, and/or another type of semiconductor processing tool.

As shown in FIG. 9, process 900 may include providing a semiconductor device in a processing chamber of a plasma tool (block 910). For example, one or more semiconductor processing tools may be used to provide a semiconductor device (e.g., a semiconductor device 100) in a processing chamber (e.g., a processing chamber 410) of a plasma tool (e.g., a semiconductor processing tool 408), as described herein. In some implementations, a material of a lid (e.g., a lid 414) of the processing chamber includes a metal oxide material or a metal-containing ceramic material. In some implementations, the semiconductor device includes a recess (e.g., a recess 402, a recess 502, a recess 602, a recess 604) in a dielectric layer (e.g., an ILD layer 126) and in an ESL (e.g., an ESL 128) of an interconnect layer (e.g., an interconnect layer 104) of the semiconductor device. In some implementations, the dielectric layer is above the ESL. In some implementations, the dielectric layer and the ESL contain different dielectric materials. In some implementations, the ESL is above a contact structure (e.g., a source/drain contact structure 122) and a gate structure (e.g., a gate structure 116) of an integrated circuit device (e.g., an integrated circuit device 110) in a device layer (e.g., a device layer 102) of the semiconductor device.

As further shown in FIG. 9, process 900 may include performing a plasma treatment operation to treat ends of the ESL exposed in the recess (block 920). For example, one or more semiconductor processing tools may be used to perform a plasma treatment operation to treat ends of the ESL exposed in the recess, as described herein. In some implementations, the plasma treatment operation results in formation of oxide regions 138 (e.g., oxide regions 138) on the ends of the ESL. In some implementations, a first dielectric constant of the oxide regions is less than a second dielectric constant of the ESL. In some implementations, the material of the lid of the processing chamber resists damage to the lid from the plasma treatment operation.

Process 900 may include additional implementations, such as any single implementation or any combination of implementations described below and/or in connection with one or more other processes described elsewhere herein.

In a first implementation, the material of the lid includes at least one of a zirconium oxide material (ZrOₓ), an aluminum oxide material (AlₓO_{y}), an yttrium (Y)-containing ceramic, an aluminum (Al)-containing ceramic, or a chromium (Cr)-containing ceramic.

In a second implementation, alone or in combination with the first implementation, sidewalls (e.g., sidewalls 412) of the processing chamber are coated with a coating that contains at least one of an alkaline earth fluoride material, a boron nitride (BN) material, a carbide material, or a metal pnictide material.

In a third implementation, alone or in combination with one or more of the first and second implementations, the coating resists damage to the sidewalls of the processing chamber from the plasma treatment operation.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

In this way, one or more dielectric layers in a semiconductor device are treated using an oxidation treatment process to tune the dielectric constant of the one or more dielectric layers. For example, an ESL in an interconnect layer of the semiconductor device may be formed of a high-k dielectric material such as silicon nitride (SiₓN_{y}), which provides etch selectivity for the ESL relative to other dielectric layers in the interconnect layer. The etch selectivity of the ESL may facilitate formation of a recess through the ESL and through other dielectric layers in the interconnect layer for formation of a conductive structure (e.g., a source/drain interconnect, a gate interconnect) in the recess. After formation of the recess, an oxidation treatment operation may be performed to oxidize the exposed ends of the ESL in the recess using an oxygen-based reactant. Oxygen (O) in the oxygen-based reactant and silicon (Si) in the ends of the ESL exposed in the recess may react to form a layer of silicon oxide (SiOₓ) on the ends of the ESL. The conductive structure may be formed in the recess after the oxidation treatment operation. The band gap of the silicon oxide (SiOₓ) on the ends of the ESL is greater than that of the band gap of the material (e.g., silicon nitride) of the ESL. The greater band gap of the silicon oxide (SiOₓ) on the ends of the ESL results in the layer of silicon oxide (SiOₓ) being less susceptible to current leakage through tunneling, hot-carrier injection, and/or thermionic emission. In this way, the oxidation treatment process may be used to achieve low current leakage in the semiconductor device between the source/drain interconnects and gate interconnects of transistors in the semiconductor device, between the source/drain interconnects and the gate structures of the transistors, and/or between the gate interconnects and the source/drain contacts of the transistors.

As described in greater detail above, some implementations described herein provide a semiconductor device. The semiconductor device includes a device layer. The semiconductor device includes an integrated circuit device in the device layer. The semiconductor device includes an interconnect layer over the integrated circuit device. The interconnect layer includes a plurality of ILD layers, a plurality of ESLs interleaving the plurality of ILD layers, and a plurality of metallization structures in the plurality of ILD layers a plurality of interconnect structures. A first interconnect structure of the plurality of interconnect structures extends vertically through a first ESL of the plurality of ESLs to couple two or more of the plurality of metallization structures. A second interconnect structure extends vertically through a second ESL of the plurality of ESLs to couple the integrated circuit device to the interconnect layer. A first dielectric constant of the second ESL is greater than a second dielectric constant of at least one of the plurality of ILD layers. The interconnect layer further includes oxide regions laterally between the second ESL and sidewalls of the second interconnect structure. A third dielectric constant of the oxide regions is less than the first dielectric constant of the second ESL.

As described in greater detail above, some implementations described herein provide a method. The method includes forming a recess in a dielectric layer and in an ESL of an interconnect layer of a semiconductor device. The dielectric layer is above the ESL. The ESL is above a contact structure and a gate structure of an integrated circuit device in a device layer of the semiconductor device. The method includes performing an oxidation treatment operation on ends of the ESL exposed in the recess. The oxidation treatment operation results in formation of oxide regions on the ends of the ESL. A first material of the oxide regions and a second material of the ESL are different materials that have different band gaps. The method includes forming a conductive structure of the interconnect layer in the recess.

As described in greater detail above, some implementations described herein provide a method. The method includes providing a semiconductor device in a processing chamber of a plasma tool. A material of a lid of the processing chamber comprises a metal oxide material or a metal-containing ceramic material. The semiconductor device comprises a recess in a dielectric layer and in an ESL of an interconnect layer of the semiconductor device. The dielectric layer is above the ESL. The dielectric layer and the ESL contain different dielectric materials. The ESL is above a contact structure and a gate structure of an integrated circuit device in a device layer of the semiconductor device. The method includes performing a plasma treatment operation to treat ends of the ESL exposed in the recess, where the plasma treatment operation results in formation of oxide regions on the ends of the ESL. A first dielectric constant of the oxide regions is less than a second dielectric constant of the ESL. The material of the lid of the processing chamber resists damage to the lid from the plasma treatment operation.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a device layer;
an integrated circuit device in the device layer; and
an interconnect layer, over the integrated circuit device, comprising:
a plurality of interlayer dielectric (ILD) layers;
a plurality of etch stop layers (ESLs) interleaving the plurality of ILD layers;
a plurality of metallization structures in the plurality of ILD layers;
a plurality of interconnect structures,
wherein a first interconnect structure of the plurality of interconnect structures extends vertically through a first ESL of the plurality of ESLs to couple two or more of the plurality of metallization structures,
wherein a second interconnect structure of the plurality of interconnect structures extends vertically through a second ESL of the plurality of ESLs to couple the integrated circuit device to the interconnect layer, and
wherein a first dielectric constant of the second ESL is greater than a second dielectric constant of at least one of the plurality of ILD layers; and
oxide regions laterally between the second ESL and sidewalls of the second interconnect structure,
wherein a third dielectric constant of the oxide regions is less than the first dielectric constant of the second ESL.

2. The semiconductor device of claim 1, wherein a bottom surface of the second interconnect structure is coupled to a top surface of a source/drain contact of the integrated circuit device;
wherein the second ESL comprises silicon nitride (SiₓN_{y}); and
wherein the oxide regions comprise silicon oxide (SiOₓ).

3. The semiconductor device of claim 1, wherein a first portion of a top surface of an oxide region of the oxide regions is in contact with an ILD layer, of the plurality of ILD layers, above the second ESL; and
wherein a second portion of the top surface of the oxide region is in contact with the second interconnect structure.

4. The semiconductor device of claim 3, wherein the oxide region is laterally between the second ESL and a first segment of the sidewalls of the second interconnect structure;
wherein a second segment of the sidewalls of the second interconnect structure is laterally adjacent to the ILD layer that is above the second ESL; and
wherein the sidewalls of the second interconnect structure comprise a stepped segment that transitions between the first segment and the second segment.

5. The semiconductor device of claim 1, wherein a bottom surface of the second interconnect structure is located at a lower vertical position in the semiconductor device than a bottom surface of the second ESL and a bottom surface of an oxide region of the oxide regions.

6. The semiconductor device of claim 1, wherein a bottom surface of the second interconnect structure is coupled to a top surface of a gate structure of the integrated circuit device;
wherein the second ESL comprises silicon nitride (SiₓN_{y}); and
wherein the oxide regions comprise silicon oxide (SiOₓ).

7. The semiconductor device of claim 1, wherein a first band gap of a first material of the oxide regions is less than a second band gap of a second material of the second ESL.

8. The semiconductor device of claim 1, wherein an oxygen concentration, in a portion of an oxide region of the oxide regions at an interface between the oxide region and the sidewalls of the interconnect structure, is greater than a nitrogen concentration in the portion of the oxide region at the interface between the oxide region and the sidewalls of the interconnect structure.

9. A method, comprising:
forming a recess in a dielectric layer and in an etch stop layer (ESL) of an interconnect layer of a semiconductor device,
wherein the dielectric layer is above the ESL, and
wherein the ESL is above a contact structure and a gate structure of an integrated circuit device in a device layer of the semiconductor device;
performing an oxidation treatment operation on ends of the ESL exposed in the recess,
wherein the oxidation treatment operation results in formation of oxide regions on the ends of the ESL, and
wherein a first material of the oxide regions and a second material of the ESL are different materials that have different band gaps; and
forming a conductive structure of the interconnect layer in the recess.

10. The method of claim 9, wherein performing the oxidation treatment operation comprises:
performing the oxidation treatment operation using an oxygen-containing reactant that includes an oxygen-containing plasma.

11. The method of claim 9, wherein performing the oxidation treatment operation comprises:
performing the oxidation treatment operation using an oxygen-containing reactant that includes an oxygen-containing gas.

12. The method of claim 11, wherein the oxygen-containing gas comprises at least one of:
oxygen (O₂),
nitrous oxide (NOₓ),
water vapor (H₂O), or
ozone (O₃).

13. The method of claim 9, wherein performing the oxidation treatment operation comprises:
performing the oxidation treatment operation using a hydrogen (H₂) gas.

14. The method of claim 9, wherein a portion of the ends of the ESL is consumed to form a first portion of an oxide region of the oxide regions; and
wherein a second portion of the oxide region grows on the first portion.

15. The method of claim 9, wherein forming the recess comprises:
forming the recess such that a top surface of the contact structure is exposed through the recess; and
wherein forming the conductive structure comprises:
forming a source/drain interconnect structure in the recess on the contact structure.

16. The method of claim 9, wherein forming the recess comprises:
forming the recess such that a top surface of the gate structure is exposed through the recess; and
wherein forming the conductive structure comprises:
forming a gate interconnect structure in the recess on the gate structure.

17. A method, comprising:
providing a semiconductor device in a processing chamber of a plasma tool,
wherein a material of a lid of the processing chamber comprises a metal oxide material or a metal-containing ceramic material,
wherein the semiconductor device comprises a recess in a dielectric layer and in an etch stop layer (ESL) of an interconnect layer of the semiconductor device,
wherein the dielectric layer is above the ESL,
wherein the dielectric layer and the ESL contain different dielectric materials, and
wherein the ESL is above a contact structure and a gate structure of an integrated circuit device in a device layer of the semiconductor device; and
performing a plasma treatment operation to treat ends of the ESL exposed in the recess,
wherein the plasma treatment operation results in formation of oxide regions on the ends of the ESL,
wherein a first dielectric constant of the oxide regions is less than a second dielectric constant of the ESL, and
wherein the material of the lid of the processing chamber resists damage to the lid from the plasma treatment operation.

18. The method of claim 17, wherein the material of the lid comprises at least one of:
a zirconium oxide material (ZrOₓ),
an aluminum oxide material (AlₓO_{y}),
an yttrium (Y)-containing ceramic,
an aluminum (Al)-containing ceramic, or
a chromium (Cr)-containing ceramic.

19. The method of claim 17, wherein sidewalls of the processing chamber are coated with a coating that contains at least one of:
an alkaline earth fluoride material,
a boron nitride (BN) material,
a carbide material, or
a metal pnictide material.

20. The method of claim 19, wherein the coating resists damage to the sidewalls of the processing chamber from the plasma treatment operation.
